(19) United States
(12) Patent Application Publication
(10) Pub. No.: US 2017/0155020 A1
(43) Pub. Date: Jun. 1, 2017

(54) WAVELENGTH-CONVERTING MATERIAL AND APPLICATION THEREOF

(71) Applicant: Lextar Electronics Corporation, Hsinchu (TW)

(72) Inventors: Shin-Ying Lin, Tainan City (TW); Hung-Chia Wang, Taichung City (TW); An-Cih Tang, Taichung City (TW); Ru-Shi Liu, New Taipei City (TW); Tzong-Liang Tsai, Taichung City (TW); Yu-Chun Lee, Zhubei City (TW); Ching-Yi Chen, New Taipei City (TW); Hung-Chun Tong, New Taipei City (TW)

(21) Appl. No.: 15/358,339

(22) Filed: Nov. 22, 2016

Related U.S. Application Data
(60) Provisional application No. 62/260,657, filed on Nov. 30, 2015.
(60) Provisional application No. 62/291,552, filed on Feb. 5, 2016.
(60) Provisional application No. 62/334,502, filed on May 11, 2016.

(30) Foreign Application Priority Data
Sep. 26, 2016 (TW) 105131057

(51) Int. Cl. H01L 33/50; H01L 33/60; C09K 11/66; H01L 33/38

(52) U.S. Cl. CPC H01L 33/502; H01L 33/507; H01L 33/38; H01L 33/60; C09K 11/665; H01L 2933/0083; Y10S 977/774; Y10S 977/813; Y10S 977/95; B82Y 20/00

(57) ABSTRACT

A wavelength-converting material and an application thereof are provided. The wavelength-converting material includes an all-inorganic perovskite quantum dot having a chemical formula of CsPb(ClₐBr_{1-a-b}I_{b})₃, wherein 0≦a≦1, 0≦b≦1.

This application claims the benefit of U.S. provisional application Ser. No. 62/260,657, filed Nov. 30, 2015; U.S. provisional application Ser. No. 62/291,552, filed Feb. 5, 2016; U.S. provisional application Ser. No. 62/334,502, filed May 11, 2016; Taiwan application Serial No. 105131057, filed Sep. 26, 2016, the subject matters of which are incorporated herein by reference.

### BACKGROUND OF THE INVENTION

Field of the Invention

The invention relates in general to a wavelength-converting material and an application thereof, and particularly relates to a wavelength-converting material comprising an all-inorganic perovskite quantum dot and an application thereof.

Description of the Related Art

Currently, a common light emitting material often uses a phosphor powder and a quantum dot. However, market for the phosphor powder is almost close to a saturation condition. A full width at half maximum (FWHM) of an emission spectrum of the phosphor powder is wide mostly, and is difficult to improve dramatically. This results in technical limits in an application for a device. Therefore, the research trend is towards the quantum dot field.

Nano materials have a particle size of 1 nm to 100 nm, and can be further classified according to the size. Semiconductor nano crystals (NCs) are referred to as quantum dots (QDs), and a particle size of which is classified into a nano material of zero dimension. The nano material is widely used for an application of a light emitting diode, a solar cell, a biomarker, etc. Unique properties of its optical, electrical and magnetic characteristics make the nano material being an object researched for newly developed industry.

The quantum dot has an emission property having a narrow FWHM. Therefore, the quantum dot can be applied in a light emitting diode device to solve a problem of an insufficient wide color gamut of a conventional phosphor powder, attracting attention extraordinarily.

### SUMMARY OF THE INVENTION

The present disclosure relates to a wavelength-converting material and an application thereof.

According to a concept of the present disclosure, a light emitting device is provided. The light emitting device comprises a light emitting diode chip and a wavelength-converting material. The wavelength-converting material is capable of being excited by a first light emitted from the light emitting diode chip to emit a second light having a wavelength different from a wavelength of the first light. The wavelength-converting material comprises an all-inorganic perovskite quantum dot having a chemical formula of CsPb(ClₐBr_{1-a-b}I_{b})₃, wherein 0≦a≦1, 0≦b≦1.

According to another concept of the present disclosure, a wavelength-converting material is provided. The wavelength-converting material comprises at least two kinds of all-inorganic perovskite quantum dots having different characteristics and having a chemical formula of CsPb(ClₐBr_{1-a-b}I_{b})₃, wherein 0≦a≦1, 0≦b≦1.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 illustrates a light emitting diode chip according to an embodiment.

FIG. 2 illustrates a light emitting diode chip according to an embodiment.

FIG. 3 illustrates a light emitting diode package structure according to an embodiment.

FIG. 4 illustrates a light emitting diode package structure according to an embodiment.

FIG. 5 illustrates a light emitting diode package structure according to an embodiment.

FIG. 6 illustrates a light emitting diode package structure according to an embodiment.

FIG. 7 illustrates a light emitting diode package structure according to an embodiment.

FIG. 8 illustrates a light emitting diode package structure according to an embodiment.

FIG. 9 illustrates a light emitting diode package structure according to an embodiment.

FIG. 10 illustrates a light emitting diode package structure according to an embodiment.

FIG. 11 illustrates a light emitting diode package structure according to an embodiment.

FIG. 12 illustrates a light emitting diode package structure according to an embodiment.

FIG. 13 illustrates a light emitting diode package structure according to an embodiment.

FIG. 14 illustrates a light emitting diode package structure according to an embodiment.

FIG. 15 illustrates a light emitting diode package structure according to an embodiment.

FIG. 16 illustrates a light emitting diode package structure according to an embodiment.

FIG. 17 illustrates a light emitting diode package structure according to an embodiment.

FIG. 18 illustrates a side type back light module according to an embodiment.

FIG. 19 illustrates a direct type back light module according to an embodiment.

FIG. 20 illustrates a three dimensional view of a light emitting diode package structure according to an embodiment.

FIG. 21 illustrates a perspective view of a light emitting diode package structure according to an embodiment.

FIG. 22 illustrates a three dimensional view of a light emitting diode package structure according to an embodiment.

FIG. 23 to FIG. 26 illustrate a manufacturing method for a light emitting device according to an embodiment.

FIG. 27 illustrates a plug-in light emitting unit according to an embodiment.

FIG. 28 illustrates a plug-in light emitting unit according to an embodiment.

FIG. 29 illustrates a plug-in light emitting unit according to an embodiment.

FIG. 30 illustrates a light emitting device according to an embodiment.

FIG. 31 illustrates a three dimensional view of a portion of a light emitting device corresponding to a pixel according to an embodiment.

FIG. 32 illustrates a cross-section view of a portion of a light emitting device corresponding to a pixel according to an embodiment.

FIG. 33 shows X-ray diffraction patterns of all-inorganic perovskite quantum dots according to embodiments.

FIG. 34 shows photoluminescence (PL) spectrums of all-inorganic perovskite quantum dot according to embodiments.

FIG. 35 shows positions of all-inorganic perovskite quantum dots in a CIE diagram according to embodiments.

FIG. 36 shows X-ray diffraction patterns of all-inorganic perovskite quantum dots according to embodiments.

FIG. 37 shows PL spectrums of all-inorganic perovskite quantum dot according to embodiments.

FIG. 38 shows positions of all-inorganic perovskite quantum dots in a CIE diagram according to embodiments.

FIG. 39 shows PL spectrums of all-inorganic perovskite quantum dot according to embodiments.

FIG. 40 shows a PL spectrum of a light emitting diode package structure comprising a blue light emitting diode chip with a red all-inorganic perovskite quantum dot together with a yellow phosphor powder according to an embodiment.

FIG. 41 shows a gamut of colors in a CIE diagram of a light emitting diode package structure according to an embodiment.

FIG. 42 is a PL spectrum of all-inorganic perovskite quantum dots of CsPbBr₃ and CsPbI₃ excited by a light emitting diode chip according to embodiments.

FIG. 43 shows gamuts of colors in a CIE diagram of all-inorganic perovskite quantum dots of CsPbBr₃ and CsPbI₃ excited by a light emitting diode chip.

### DETAILED DESCRIPTION OF THE INVENTION

Embodiment of the present disclosure relate to a wavelength-converting material and its applications. The wavelength-converting material comprises an all-inorganic perovskite quantum dot having a chemical formula of CsPb(ClₐBr_{1-a-b}I_{b})₃. A wavelength of an emitted light from the all-inorganic perovskite quantum dot can be adjusted according to a composition and/or a size of the all-inorganic perovskite quantum dot, and thus the all-inorganic perovskite quantum dot is suitable for a wide application. In addition, the all-inorganic perovskite quantum dot can exhibit an emission spectrum having a narrow full width at half maximum (FWHM) and a good pure quality of color. Therefore, the all-inorganic perovskite quantum dot can be applied in use of a light emitting device such as a lighting source or for a display device, etc. to improve an emitting effect such as a color rendering, an accuracy of color, a color gamut, etc.

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

In embodiments, the light emitting device comprises a light emitting diode chip and the wavelength-converting material. The wavelength-converting material is capable of being excited by a first light emitted from the light emitting diode chip to emit a second light having a wavelength different from a wavelength of the first light.

In embodiments, the wavelength-converting material comprises the all-inorganic perovskite quantum dot having the chemical formula of CsPb(ClₐBr_{1-a-b}I_{b})₃, wherein 0≦a≦1, 0≦b≦1. In embodiments, the all-inorganic perovskite quantum dot has good quantum efficiency, exhibiting an emission spectrum having a narrow full width at half maximum (FWHM) and good pure quality of color, and can improve a light emitting effect as being applied in the light emitting device.

The all-inorganic perovskite quantum dot may be adjusted in a composition and/or a size to modify a band gap to change a color of an emission light (a wavelength of the second light), such as blue, green, red color gamuts, flexible in application.

The all-inorganic perovskite quantum dot has a nanometer size. For example, the all-inorganic perovskite quantum dot has a particle diameter in a range of about 1 nm to 100 nm, such as about 1 nm to 20 nm.

For example, the all-inorganic perovskite quantum dot has a chemical formula of CsPb(ClₐBr₁₋ₐ)₃, 0≦a≦1. Alternatively, the all-inorganic perovskite quantum dot has a chemical formula of CsPb(Br_{1-b}I_{b})₃, 0≦b≦1.

In embodiments, the all-inorganic perovskite quantum dot may be a blue quantum dot (blue all-inorganic perovskite quantum dot). For example, in an example of the all-inorganic perovskite quantum dot having the chemical formula of CsPb(ClₐBr₁₋ₐ)₃, the all-inorganic perovskite quantum dot is the blue quantum dot when complying with 0<a≦1, and/or having a particle diameter in a range of about 7 nm to 10 nm. In an embodiment, the (second) light emitted from the excited blue quantum dot has a wave peak at a position of about 400 nm to 500 nm, or/and a full width at half maximum (FWHM) of about 10 nm to 30 nm.

In embodiments, the all-inorganic perovskite quantum dot may be a red quantum dot (red all-inorganic perovskite quantum dot). For example, in an example of the all-inorganic perovskite quantum dot having the chemical formula of CsPb(Br_{1-b}I_{b})₃, the all-inorganic perovskite quantum dot is the red quantum dot when complying with 0.5≦b≦1, and/or having a particle diameter in a range of about 10 nm to 14 nm. In an embodiment, the (second) light emitted from the excited red quantum dot has a wave peak at a position of about 570 nm to 700 nm, or/and a FWHM of about 20 nm to 60 nm.

In embodiments, the all-inorganic perovskite quantum dot may be a green quantum dot (green all-inorganic perovskite quantum dot). For example, in an example of the all-inorganic perovskite quantum dot having the chemical formula of CsPb(Br_{1-b}I_{b})₃, the all-inorganic perovskite quantum dot is the green quantum dot when complying with 0≦b<0.5, and/or having a particle diameter in a range of about 8 nm to 12 nm. In an embodiment, the second light emitted from the excited green all-inorganic perovskite quantum dot has a wave peak at a position of about 500 nm to 570 nm, or/and a FWHM of about 15 nm to 40 nm.

In embodiments, the wavelength-converting material (or a wavelength converting layer) used in the light emitting device is not limited to one kind of the all-inorganic perovskite quantum dot. In other words, the all-inorganic perovskite quantum dots of more than one kind (i.e. two kinds, three kinds, four kinds, or more kinds) having different characteristics may be used. The characteristics of the all-inorganic perovskite quantum dot can be adjusted by a chemical formula and/or a size.

For example, the all-inorganic perovskite quantum dot may comprise a first all-inorganic perovskite quantum dot and a second all-inorganic perovskite quantum dot having different characteristics from each other and mixed together. In other embodiments, the all-inorganic perovskite quantum dot may further comprise a third all-inorganic perovskite quantum dot, a fourth all-inorganic perovskite quantum dot, etc., each having a characteristic different from the characteristics of the first all-inorganic perovskite quantum dot and the second all-inorganic perovskite quantum dot, and mixed together.

For example, the first all-inorganic perovskite quantum dot and the second all-inorganic perovskite quantum dot may have different particle diameters. In other embodiments, the all-inorganic perovskite quantum dot may further comprise the third all-inorganic perovskite quantum dot, the fourth all-inorganic perovskite quantum dot, etc., having a particle diameter different from the article diameters of the first all-inorganic perovskite quantum dot and the second all-inorganic perovskite quantum dot.

In some embodiments, the first all-inorganic perovskite quantum dot and the second all-inorganic perovskite quantum dot both have the chemical formula of CsPb(ClₐBr_{1-a-b}I_{b})₃, 0≦a≦1, 0≦b≦1. The first all-inorganic perovskite quantum dot and the second all-inorganic perovskite quantum dot have different a, and/or have different b. This concept may be also applied for examples using the all-inorganic perovskite quantum dots of three kinds, four kinds, or more kinds.

For example, the first all-inorganic perovskite quantum dot and the second all-inorganic perovskite quantum dot may be selected from the group consisting of the red (all-inorganic perovskite) quantum dot having the chemical formula of CsPb(Br_{1-b}I_{b})₃ with 0.5≦b≦1, the green (all-inorganic perovskite) quantum dot having the chemical formula of CsPb(Br_{1-b}I_{b})₃ with 0≦b<0.5, and the blue (all-inorganic perovskite) quantum dot having the chemical formula of CsPb(ClₐBr₁₋ₐ)₃ with 0<a≦1. Optionally, the first all-inorganic perovskite quantum dot and the second all-inorganic perovskite quantum dot may be selected from the group consisting of the red all-inorganic perovskite quantum dot having the particle diameter in a range of about 10 nm to 14 nm, the green all-inorganic perovskite quantum dot having the particle diameter in a range of about 8 nm to 12 nm, and the blue all-inorganic perovskite quantum dot having the particle diameter in a range of about 7 nm to 10 nm.

The all-inorganic perovskite quantum dot may be used in various applications of light emitting devices, such as a lighting lamp or a light emitting module (front light module, back light module) of a display for a display screen of a smart phone, a television screen, etc., a pixel or a sub pixel for a display panel. In addition, when more kinds of the all-inorganic perovskite quantum dots with different compositions (i.e. more different emission wavelengths) are used, the light emitting device can achieve a wider emission spectrum, even achieve a full spectrum for demands. Therefore, using the all-inorganic perovskite quantum dot according to the present disclosure in the display device can improve a color gamut, a color purity, a color trueness, NTSC, etc.

For example, in some embodiments, the light emitting device may comprise at least two kinds of the all-inorganic perovskite quantum dots having the chemical formula of CsPb(Br_{1-b}I_{b})₃ of different characteristics, so as to have a NTSC equal to or higher than 90%. In some embodiments, the light emitting device may comprise at least four kinds of the all-inorganic perovskite quantum dots having the chemical formula of CsPb(Br_{1-b}I_{b})₃ of different characteristics, so as to exhibit a general color rendering index (Ra) of at least 75.

For example, the light emitting device may be applied in a light emitting diode package structure. In an example for a white light emitting diode package structure, the wavelength-converting material may comprise the green all-inorganic perovskite quantum dot and the red all-inorganic perovskite quantum dot, which are excited by a blue light emitting diode; or the wavelength-converting material may comprise the red all-inorganic perovskite quantum dot and a yellow phosphor powder, which are excited by the blue light emitting diode; or the wavelength-converting material may comprise the green all-inorganic perovskite quantum dot and a red phosphor powder, which are excited by the blue light emitting diode; or the wavelength-converting material comprise the red all-inorganic perovskite quantum dot, the green all-inorganic perovskite quantum dot and the blue all-inorganic perovskite quantum dot, which are excited by a UV light emitting diode.

The wavelength-converting material (or the wavelength converting layer) may further comprise other kinds of phosphor material, comprising an inorganic phosphor material and/or an organic phosphor material used together with the all-inorganic perovskite quantum dot. Herein, the inorganic phosphor material/the organic phosphor material may comprise a phosphor material of a quantum dot structure and/or non-quantum dot structure distinct from the all-inorganic perovskite quantum dot of CsPb(ClₐBr_{1-a-b}I_{b})₃.

For example, the inorganic phosphor material may comprise an aluminate phosphor powder (such as LuYAG, GaYAG, YAG, etc.), a silicate phosphor powder, a sulfide phosphor powder, a nitride phosphor powder, a fluoride phosphor powder, etc. The organic phosphor material may comprise a single molecule structure, a polymolecule structure, an oligomer, or a polymer. A compound of the organic phosphor material may comprise a group of perylene, a group of benzimidazole, a group of naphthalene, a group of anthracene, a group of phenanthrene, a group of fluorene, a group of 9-fluorenone, a group of carbazole, a group of glutarimide, a group of 1, 3-diphenylbenzene, a group of benzopyrene, a group of pyrene, a group of pyridine, a group of thiophene, a group of 2, 3-dihydro-1H-benzo[de]isoquinoline-1, 3-dione, a group of benzimidazole, or a combination thereof. For example, a yellow phosphor material such as YAG:Ce, and/or an inorganic yellow phosphor powder comprising a component of a oxynitride, a silicate or a nitride, and/or an organic yellow phosphor powder. For example, the red phosphor powder may comprise the fluoride comprising A₂[MF₆]:Mn⁴⁺, wherein A is selected from the group consisting of Li, Na, K, Rb, Cs, NH₄, and a combination thereof, M is selected from the group consisting of Ge, Si, Sn, Ti, Zr and a combination thereof. Optionally, the red phosphor powder may comprise (Sr, Ca)S:Eu, (Ca, Sr)₂Si₅N₈:Eu, CaAlSiN₃:Eu, (Sr, Ba)₃SiO₅:Eu.

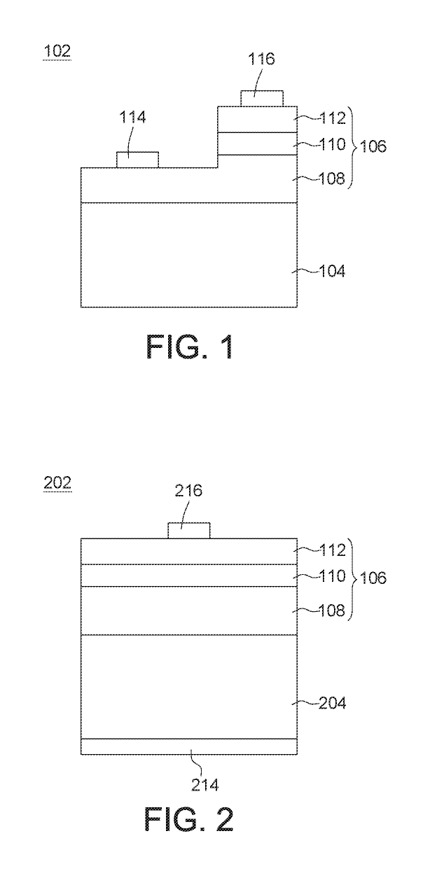

FIG. 1 illustrates a light emitting diode chip 102 according to an embodiment. The light emitting diode chip 102 comprises a substrate 104, an epitaxial structure 106, a first electrode 114 and a second electrode 116. The epitaxial structure 106 comprises a first type semiconductor layer 108, an active layer 110 and a second type semiconductor layer 112 stacked from the substrate 104 in order. The first electrode 114 and the second electrode 116 are connected to the first type semiconductor layer 108 and the second type semiconductor layer 112 respectively. The substrate 104 may comprise an insulating material (such as a sapphire material) or a semiconductor material. The first type semiconductor layer 108 and the second type semiconductor layer 112 have opposing conductivity types. For example, the first type semiconductor layer 108 has an N-type semiconductor layer, while the second type semiconductor layer 112 has a P-type semiconductor layer, wherein the first electrode 114 is an N electrode, and the second electrode 116 is a P electrode. For example, the first type semiconductor layer 108 has a P-type semiconductor layer, while the second type semiconductor layer 112 has an N-type semiconductor layer, wherein the first electrode 114 is a P electrode, and the second electrode 116 is an N electrode. The light emitting diode chip 102 may be disposed in a face-up type manner or a flip-chip type manner. In an example relating to the flip-chip type manner, the light emitting diode chip 102 is placed upside down so that the first electrode 114 and the second electrode 116 face a base plate such as a circuit board and are bonded to contact pads through solders.

FIG. 2 illustrates a light emitting diode chip 202 according to another embodiment. The light emitting diode chip 202 is a vertical light emitting diode chip. The light emitting diode chip 202 comprises a substrate 204 and the epitaxial structure 106. The epitaxial structure 106 comprises the first type semiconductor layer 108, the active layer 110 and the second type semiconductor layer 112 stacked from the substrate 204 in order. A first electrode 214 and a second electrode 216 are connected to the substrate 204 and the second type semiconductor layer 112 respectively. The material of substrate 204 comprises a metal, an alloy, a conductive, a semiconductor, or a combination thereof. The substrate 204 may comprise a semiconductor material having a conductivity type same with a conductivity type of the first type semiconductor layer 108; or a conductive material capable of forming an Ohmi contact to the first type semiconductor layer 108, such as a metal, etc. For example, the first type semiconductor layer 108 has an N-type semiconductor layer, while the second type semiconductor layer 112 has a P-type semiconductor layer, wherein the first electrode 214 is an N electrode, and the second electrode 216 is a P electrode. For example, the first type semiconductor layer 108 has a P-type semiconductor layer, while the second type semiconductor layer 112 has an N-type semiconductor layer, wherein the first electrode 214 is a P electrode, and the second electrode 216 is an N electrode.

In an embodiment, the P-type semiconductor layer may be a P-type GaN material, and the N-type semiconductor layer may be an N-type GaN material. In an embodiment, the P-type semiconductor layer may be a P-type AlGaN material, and the N-type semiconductor layer may be an N-type AlGaN material. The active layer 110 has a multiple quantum well structure.

In an embodiment, the first light emitted from the light emitting diode chip 102, 202 has a wavelength of about 220 nm to 480 nm. In an embodiment, the light emitting diode chip 102, 202 may be the UV light emitting diode chip capable of emitting the first light having a wavelength of about 200 nm to 400 nm. In an embodiment, the light emitting diode chip 102, 202 may be the blue light emitting diode chip capable of emitting the first light having a wavelength of about 430 nm to 480 nm.

In embodiments, the wavelength-converting material of the light emitting device may be contained by the wavelength converting layer, and/or doped in a transparent material. In some embodiments, the wavelength-converting material may be coated on a light emitting side of the light emitting diode chip. Examples of the light emitting devices using the wavelength-converting material are disclosed as below.

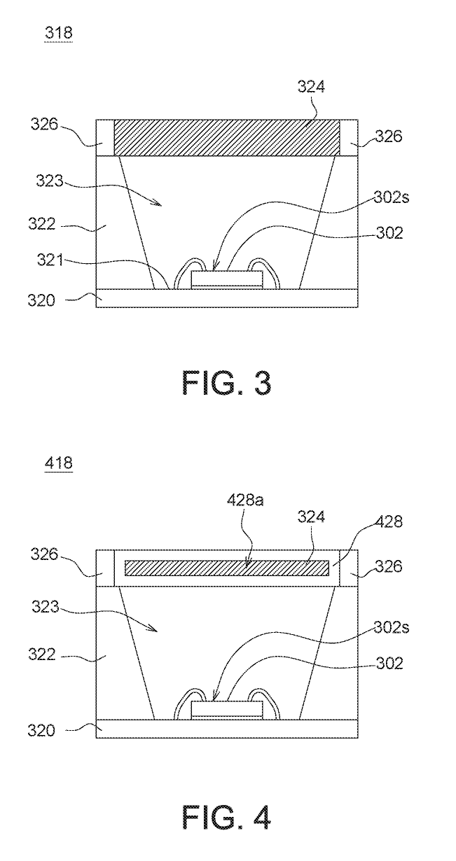

FIG. 3 illustrates a light emitting diode package structure 318 according to an embodiment. The light emitting diode package structure 318 comprises a light emitting diode chip 302, a base 320, a wavelength converting layer 324 and a reflective wall 326. The base 320 has a die bonding region 321 and a wall 322 surrounding the die bonding region 321 and defining a receiving space 323. The light emitting diode chip 302 is disposed in the receiving space 323, and may be attached on the die bonding region 321 of the base 320 through an adhesive. The wavelength converting layer 324 is on a light emitting side of the light emitting diode chip 302. In particular, the wavelength converting layer 324 is disposed over the receiving space 323 corresponding to a light emitting surface 302s of the light emitting diode chip 302, and disposed on a top surface of the wall 322. The reflective wall 326 may be disposed to surround an outer side wall of the wavelength converting layer 324 and on the top surface of the wall 322. The reflective wall 326 may comprise a material having a light-reflective characteristic and a low light leakage, such as a reflective glass, a quartz, a light-reflection attaching sheet, a polymer plastic material or other suitable materials. The polymer plastic material may comprise polymethyl methacrylate (PMMA), polyethylene terephthalate (PET), polystyrene (PS), polypropylene (PP), polyamide (PA), polycarbonate (PC), epoxy, silicone, etc., or a combination thereof. The light reflectivity of the reflective wall 326 may be adjusted by adding an additional filler particle. The filler particle may be a composite material formed by materials having different particle diameters or different materials. For example, the material for the filler particle may comprise TiO₂, SiO₂, Al₂O₃, BN, ZnO, etc. This concept may be applied for other embodiments, and will not be explained again. In the embodiment, the light emitting diode chip 302 is spaced apart from the wavelength converting layer 324 by an air gap in the receiving space 323 defined by the wall 322. For example, no substance of liquid or solid state is filled into the receiving space 323 to contact the light emitting diode chip 302.

In embodiments, the wavelength converting layer 324 comprises one kind of the wavelength-converting material or more kinds of the wavelength-converting materials. Therefore, an emission property of the light emitting diode package structure 318 may be adjusted through the wavelength converting layer 324. In some embodiments, the wavelength converting layer 324 may comprise the transparent material with the wavelength-converting material doped therein. For example, the wavelength converting layer 324 comprise at least one kind of the all-inorganic perovskite quantum dot CsPb(ClₐBr_{1-a-b}I_{b})₃ doped in the transparent material. In embodiments, the transparent material comprises a transparent gel. The transparent gel may comprise a material comprising polymethyl methacrylate (PMMA), polyethylene terephthalate (PET), polystyrene (PS), polypropylene (PP), polyamide (PA), polycarbonate (PC), polyimide (PI), polydimethylsiloxane (PDMS), epoxy, silicone, or a combination thereof, etc. In embodiments, the transparent material may comprise a glass material or a ceramic material. A glass thin film of quantum dot may be formed by a method comprising mixing the all-inorganic perovskite quantum dot and the glass material. Alternatively, a ceramic thin film of quantum dot may be formed by a method comprising mixing the all-inorganic perovskite quantum dot and the ceramic material.

In some embodiments, the wavelength converting layer 324 and the light emitting diode chip 302 are separated from each other (by the receiving space 323 in this example), preventing the wavelength converting layer 324 from being close to the light emitting diode chip 302. Therefore, the wavelength converting layer 324 can have desired heat stability and chemical stability that would be affected by the light emitting diode chip 302. In addition, lifespan of the wavelength converting layer 324 can be prolonged. Product reliability of a light emitting diode package structure can be increased. The similar concept will not be repeated hereafter.

In other transformable embodiments, the air gap of the receiving space 323 defined by the wall 322 may be filled with a transparent encapsulating compound (not shown). The transparent encapsulating compound may comprise polymethyl methacrylate (PMMA), polyethylene terephthalate (PET), polystyrene (PS), polypropylene (PP), polyamide (PA), polycarbonate (PC), polyimide (PI), polydimethylsiloxane (PDMS), an epoxy, silicone, etc., or a combination thereof, or other suitable materials. In some embodiments, the transparent encapsulating compound may be doped with one or more kinds of the wavelength-converting materials. In other transformable embodiments, one or more kinds of the wavelength-converting materials may be coated on a light emitting surface of the light emitting diode chip 302. Therefore, in addition to the wavelength converting layer 324, an emission characteristic of a light emitting diode package structure may also be adjusted by the (transparent) encapsulating compound with the wavelength-converting material doped in the (transparent) encapsulating compound and/or be adjusted by a coating layer comprising the wavelength-converting material on the light emitting surface of the light emitting diode chip 302. Kinds of the wavelength-converting materials of the wavelength converting layer 324, and/or the encapsulating compound and/or the coating layer may be adjusted properly according actual demands for products. The similar concept can be applied to other embodiments and will not be repeated hereafter.

FIG. 4 illustrates a light emitting diode package structure 418 according to an embodiment. Differences between the light emitting diode package structure 418 and the light emitting diode package structure 318 shown in FIG. 3 are disclosed as the following. The light emitting diode package structure 418 may further comprise a structural element 428 for supporting, packaging or protecting the wavelength converting layer 324. As shown in the figure, the structural element 428 has a receiving region 428a for receiving the wavelength converting layer 324 therein and covering upper, lower surfaces of the wavelength converting layer 324. The structural element 428 is disposed the top surface of the wall 322 so as to support the wavelength converting layer 324 to be above the receiving space 323 corresponding to the light emitting surface 302s of the light emitting diode chip 302. The structural element 428 may be formed by a transparent material or a light transmissive material, to avoid blocking light emitting from the wavelength converting layer 324. The structural element 428 may have a characteristic as an encapsulating material. For example, the structural element 428 may comprise quartz, glass, polymer plastic material, etc. Otherwise, the structural element 428 may be used for protecting the wavelength converting layer 324 from a foreign substance that would disadvantageously affect a property of the wavelength converting layer 324, such as moisture, oxygen gas, etc. In embodiments, the structural element 428 may a barrier film and/or a silicon titanium oxide disposed on a surface of the wavelength converting layer 324 to avoid the foreign substance such as moisture, oxygen gas, etc. The silicon titanium oxide may comprise glass material such as SiTiO₄, etc., having a light transmissive characteristic and an antioxidative property, and may be disposed on the surface of the wavelength converting layer 324 by a coating method or a sticking method as a film. The barrier film may comprise an inorganic material, such as a metal/metalloid oxide (such as SiO₂, Al₂O₃, etc.) or a metal/metalloid nitride (such as Si₃N₃, etc.). The barrier film may be a multi-layer barrier film disposed on the surface of the wavelength converting layer 324 by a coating method or a sticking method as a film. The similar concept can be applied to other embodiments and will not be repeated hereafter. The reflective wall 326 may be disposed to surround an outer side wall of the structural element 428 and on the top surface of the wall 322.

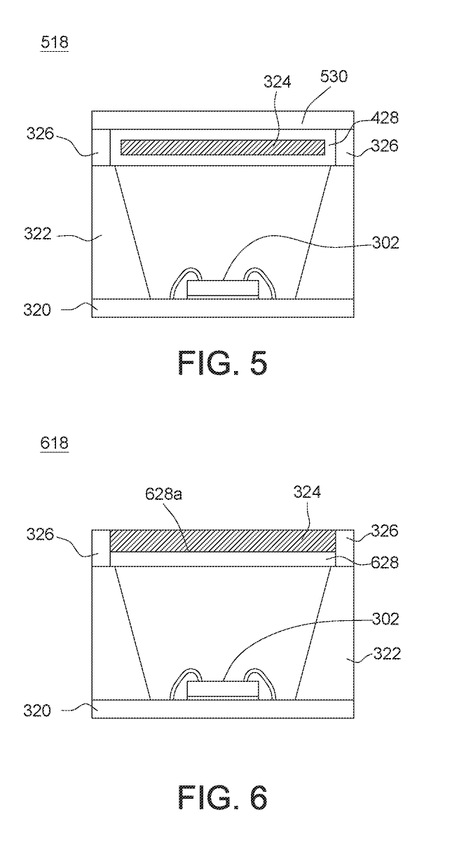

FIG. 5 illustrates a light emitting diode package structure 518 according to an embodiment. Differences between the light emitting diode package structure 518 and the light emitting diode package structure 418 shown in FIG. 4 are disclosed as following. The light emitting diode package structure 518 further comprises an optical layer 530 disposed on the reflective wall 326 and the structural element 428. The optical layer 530 may be used for adjusting a path of an emitting light. For example, the optical layer 530 may be a transparent gel with diffusion particles therein. The transparent gel comprise one or more of polymethyl methacrylate (PMMA), polyethylene terephthalate (PET), polystyrene (PS), polypropylene (PP), polyamide (PA), polycarbonate (PC), polyimide (PI), polydimethylsiloxane (PDMS), an epoxy, silicone, etc., and a combination thereof, etc. The diffusion particles may comprise TiO₂, SiO₂, Al₂O₃, BN, ZnO, etc. The diffusion particles may have uniform or various diameters. The similar concept can be applied to other embodiments and will not be repeated hereafter. For example, the optical layer 530 may be disposed on the wavelength converting layer 324 for adjusting a path of an emitting light for an application of the light emitting diode package structure 318 in FIG. 3, the light emitting diode package structure 618 in FIG. 6, the light emitting diode package structure 1018 in FIG. 10, or other structures, etc.

FIG. 6 illustrates a light emitting diode package structure 618 according to an embodiment. Differences between the light emitting diode package structure 618 and the light emitting diode package structure 318 shown in FIG. 3 are disclosed as following. The light emitting diode package structure 618 further comprises a structural element 628 having a receiving region 628a for receiving and supporting the wavelength converting layer 324 across the light emitting diode chip 302 and disposed on the wall 322. The structural element 628 on the lower surface of the wavelength converting layer 324 may be formed by a transparent material or a light transmissive material, to avoid blocking light emitting from the wavelength converting layer 324. For example, the structural element 628 may comprise quartz, a glass, a polymer plastic material, or other suitable materials. The similar concept can be applied to other embodiments and will not be repeated hereafter.

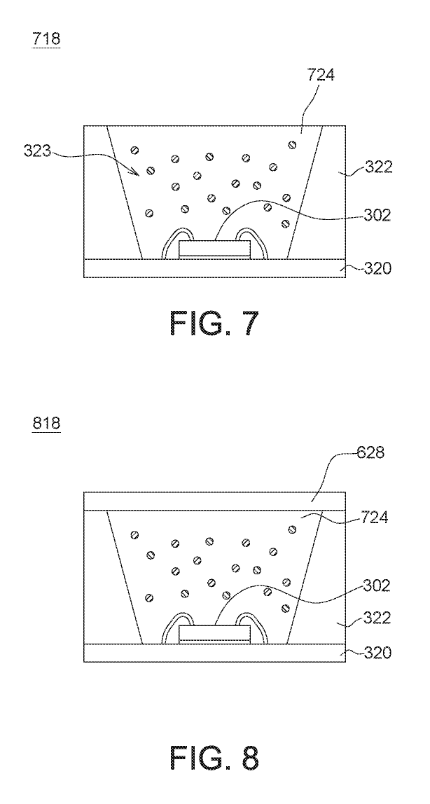

FIG. 7 illustrates a light emitting diode package structure 718 according to an embodiment. Differences between the light emitting diode package structure 718 and the light emitting diode package structure 318 shown in FIG. 3 are disclosed as following. The light emitting diode package structure 718 omits the wavelength converting layer 324 and the reflective wall 326 in FIG. 3. In addition, the light emitting diode package structure 718 comprises a wavelength converting layer 724 filling in the receiving space 323. The wavelength converting layer 724 may comprise a transparent gel and the wavelength-converting material. The transparent gel may be used as an encapsulating compound, and the wavelength-converting material may be doped in the transparent gel. The wavelength converting layer 724 may cover on the light emitting diode chip 302, or may further cover on the base 320. The transparent gel of the wavelength converting layer 724 may comprise one or more of polymethyl methacrylate (PMMA), polyethylene terephthalate (PET), polystyrene (PS), polypropylene (PP), polyamide (PA), polycarbonate (PC), polyimide (PI), polydimethylsiloxane (PDMS), an epoxy, silicone, etc., and a combination thereof, etc.

FIG. 8 illustrates a light emitting diode package structure 818 according to an embodiment. Differences between the light emitting diode package structure 818 and the light emitting diode package structure 718 shown in FIG. 7 are disclosed as following. The light emitting diode package structure 818 further comprises the structural element 628 across the wavelength converting layer 724 to be disposed on the wall 322. The structural element 628 may be used for protecting the wavelength-converting material of the wavelength converting layer 724 from a foreign substance that would cause a damage effect, such as moisture, oxygen gas, etc. In embodiments, the structural element 628 may a barrier film and/or a silicon titanium oxide disposed on a surface of the wavelength converting layer 724 to avoid the foreign substance such as moisture, oxygen gas, etc. The silicon titanium oxide may comprise a glass material such as SiTiO₄, etc., having a light transmissive characteristic and an antioxidative property, and may be disposed on the surface of the wavelength converting layer 724 by a coating method or a sticking method as a film. The barrier film may comprise an inorganic material, such as a metal/metalloid oxide (such as SiO₂, Al₂O₃, etc.) or a metal/metalloid nitride (such as Si₃N₃, etc.). The barrier film may be a multi-layer barrier film disposed on the surface of the wavelength converting layer 724 by a coating method or a sticking method as a film.

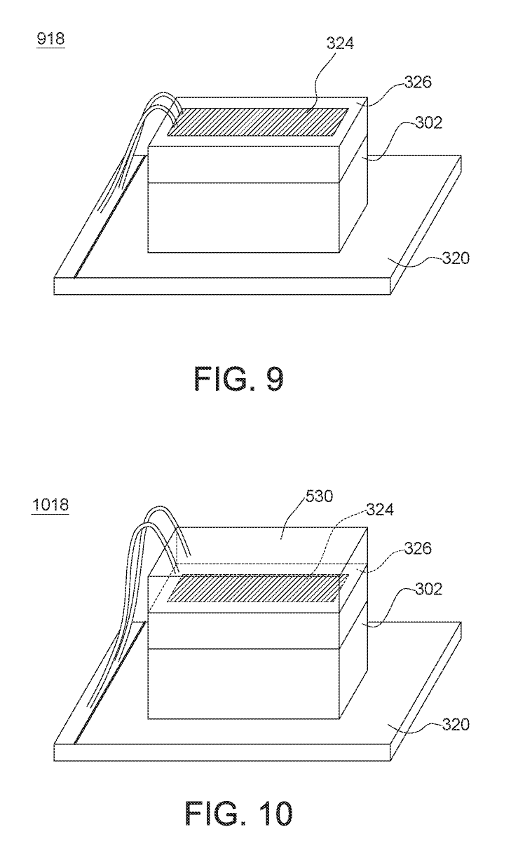

FIG. 9 illustrates a light emitting diode package structure 918 according to an embodiment. The light emitting diode package structure 918 comprises the base 320, the light emitting diode chip 302, the wavelength converting layer 324 and the reflective wall 326. The light emitting diode chip 302 is disposed on the die bonding region of the base 320. The wavelength converting layer 324 is disposed on the light emitting surface of the light emitting diode chip 302. The reflective wall 326 is disposed on a side wall of the wavelength converting layer 324. The light emitting diode chip 302 may be electrically connected to the base 320 by a wire bonding passing through an opening (not shown) of the wavelength converting layer 324.

FIG. 10 illustrates a light emitting diode package structure 1018 according to an embodiment. Differences between the light emitting diode package structure 1018 and the light emitting diode package structure 918 shown in FIG. 9 are disclosed as following. The light emitting diode package structure 1018 further comprises the optical layer 530 disposed on the wavelength converting layer 324 and the reflective wall 326. The light emitting diode chip 302 may be electrically connected to the base 320 by a wire bonding passing through an opening (not shown) of the wavelength converting layer 324 and the optical layer 530. The wire bonding may be pulled out through an upper surface or a side surface of the optical layer 530.

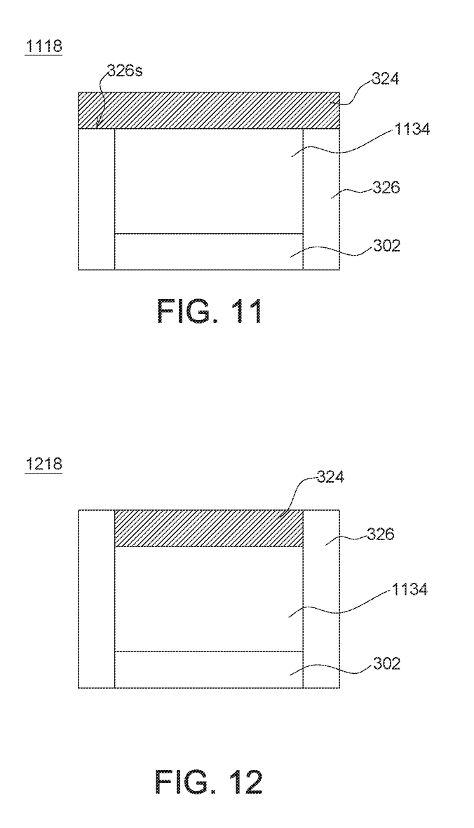

FIG. 11 illustrates a light emitting diode package structure 1118 according to an embodiment. The light emitting diode package structure 1118 comprises the light emitting diode chip 302, the wavelength converting layer 324 and the reflective wall 326. The reflective wall 326 surrounds the side wall of the light emitting diode chip 302 and defines a spaced vacancy 1134. The reflective wall 326 is higher than the light emitting diode chip 302. The wavelength converting layer 324 is disposed on a top surface 326s of the reflective wall 326. The wavelength converting layer 324 and the light emitting diode chip 302 are separated from each other by the spaced vacancy 1134 with a gap distance, preventing the wavelength converting layer 324 from being close to the light emitting diode chip 302. Therefore, the wavelength converting layer 324 can have desired heat stability and chemical stability that would be affected by the light emitting diode chip 302. In addition, lifespan of the wavelength converting layer 324 can be prolonged. Product reliability of a light emitting diode package structure can be increased. The similar concept will not be repeated hereafter.

FIG. 12 illustrates a light emitting diode package structure 1218 according to an embodiment. The light emitting diode package structure 1218 is different from the light emitting diode package structure 1118 shown in FIG. 11 in that the wavelength converting layer 324 is disposed on an inner side wall of the reflective wall 326.

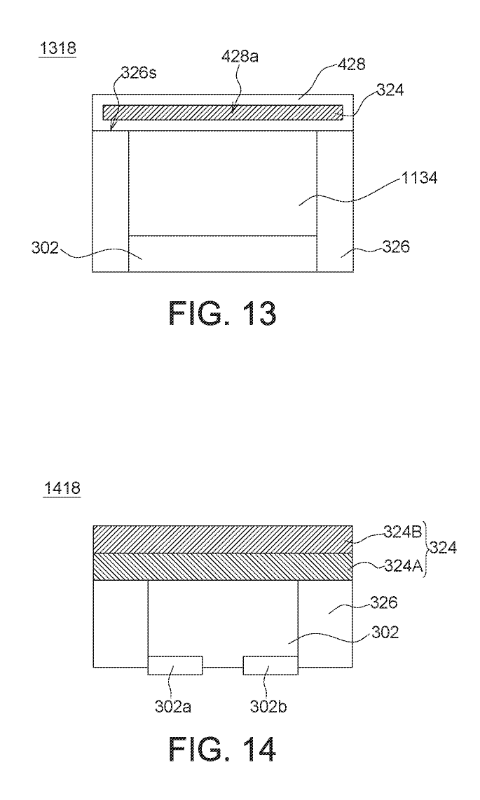

FIG. 13 illustrates a light emitting diode package structure 1318 according to an embodiment. Differences between the light emitting diode package structure 1318 and the light emitting diode package structure 1118 shown in FIG. 11 are disclosed as following. The light emitting diode package structure 1318 further comprises the structural element 428 with the wavelength converting layer 324 disposed in the receiving region 428a defined by the structural element 428, for supporting, packaging or protecting the wavelength converting layer 324. The structural element 428 covering the wavelength converting layer 324 is disposed on the top surface 326s of the reflective wall 326 to space apart from the light emitting diode chip 302 with the spaced vacancy 1134. The structural element 428 may be formed by a transparent material or a light transmissive material, to avoid blocking light emitting from the wavelength converting layer 324. The structural element 428 may have a characteristic as an encapsulating material. For example, the structural element 428 may comprise a quartz, a glass, a polymer plastic material, etc. Otherwise, the structural element 428 may be used for protecting the wavelength converting layer 324 from a foreign substance that would disadvantageously affect a property of the wavelength converting layer 324, such as moisture, oxygen gas, etc. In embodiments, the structural element 428 may a barrier film and/or a silicon titanium oxide disposed on the surface of the wavelength converting layer 324 to avoid the foreign substance such as moisture, oxygen gas, etc. The silicon titanium oxide may comprise a glass material such as SiTiO₄, etc., having a light transmissive characteristic and an antioxidative property, and may be disposed on the surface of the wavelength converting layer 324 by a coating method or a sticking method as a film. The barrier film may comprise an inorganic material, such as a metal/metalloid oxide (such as SiO₂, Al₂O₃, etc.) or a metal/metalloid nitride (such as Si₃N₃, etc.). The barrier film may be a multi-layer barrier film disposed on the surface of the wavelength converting layer 324 by a coating method or a sticking method as a film.

In an embodiment, the spaced vacancy 1134 may be an empty space not filled with a substance of liquid or solid state. The spaced vacancy 1134 may be formed by a transparent material or a light transmissive material, to avoid blocking light emitting from the wavelength converting layer 324. For example, the spaced vacancy 1134 may comprise a quartz, a glass, a polymer plastic material, or other suitable materials.

In embodiments, the light emitting diode package structure 318, 418, 518, 618, 718, 818, 918, 1018, 1118, 1218 or 1318 is for emitting a white light. In an example, the light emitting diode chip 302 may be a blue light emitting diode chip. The wavelength converting layer 324/the wavelength converting layer 724 may comprise the red all-inorganic perovskite quantum dot CsPb(Br_{1-b}I_{b})₃ and the yellow phosphor powder YAG:Ce. The red all-inorganic perovskite quantum dot complies with 0.5≦b≦1; and/or has the particle diameter in a range of about 10 nm to 14 nm.

In embodiments, the light emitting diode package structure 318, 418, 518, 618, 718, 818, 918, 1018, 1118, 1218 or 1318 is for emitting a white light. In an example, the light emitting diode chip 302 may be a blue light emitting diode chip. The wavelength converting layer 324/the wavelength converting layer 724 may comprise the green all-inorganic perovskite quantum dot CsPb(Br_{1-b}I_{b})₃ and the red all-inorganic perovskite quantum dot CsPb(Br_{1-b}I_{b})₃. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm.

In embodiments, the light emitting diode package structure 318, 418, 518, 618, 718, 818, 918, 1018, 1118, 1218 or 1318 is for emitting a white light. In an example, the light emitting diode chip 302 may be a UV light emitting diode chip. The wavelength converting layer 324/the wavelength converting layer 724 may comprise the blue all-inorganic perovskite quantum dot CsPb(ClₐBr₁₋ₐ)₃, the green all-inorganic perovskite quantum dot CsPb(Br_{1-b}I_{b})₃, the red all-inorganic perovskite quantum dot CsPb(Br_{1-b}I_{b})₃. Additionally/optionally, the blue all-inorganic perovskite quantum dot complies with 0<a≦1. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the blue all-inorganic perovskite quantum dot has the particle diameter in a range of about 7 nm to 10 nm. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm.

FIG. 14 illustrates a light emitting diode package structure 1418 according to an embodiment. The light emitting diode package structure 1418 comprises the light emitting diode chip 302, the reflective wall 326 and the wavelength converting layer 324. The reflective wall 326 is disposed on the side surface of the light emitting diode chip 302. The wavelength converting layer 324 is disposed on the upper surface (light emitting surface) of the light emitting diode chip 302. The wavelength converting layer 324 may comprise a first wavelength converting layer 324A and a second wavelength converting layer 324B having different characteristics from each other. In an embodiment, for example, the first wavelength converting layer 324A comprises the red all-inorganic perovskite quantum dot CsPb(Br_{1-b}I_{b})₃, for emitting a light having a wave peak at a wavelength position of about 570 nm to 700 nm. The second wavelength converting layer 324B comprises the green all-inorganic perovskite quantum dot CsPb(Br_{1-b}I_{b})₃, for emitting a light having a wave peak at a wavelength position of about 500 nm to 570 nm. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm. However, the present disclosure is not limited thereto. The light emitting diode chip 302 may be electrically connected to a base or a circuit board (not shown) with a first electrode 302a and a second electrode 302b by a flip chip method.

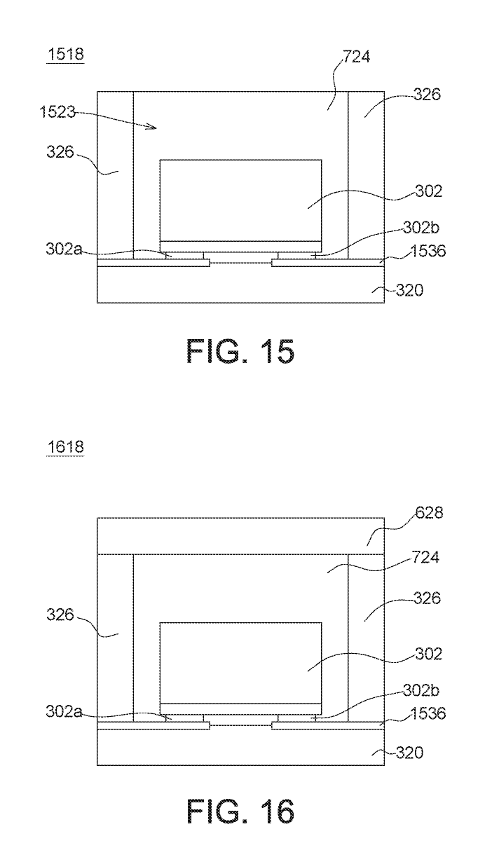

FIG. 15 illustrates a light emitting diode package structure 1518 according to an embodiment. The light emitting diode package structure 1518 comprises the base 320, the light emitting diode chip 302, the wavelength converting layer 724 and the reflective wall 326. The reflective wall 326 is disposed on the base 320 and defines a receiving space 1523. The light emitting diode chip 302 is disposed in the receiving space 1523, and electrically connected to a conductive element 1536 on the base 320 with a flip chip method. The wavelength converting layer 724 is filled in the receiving space 1523, and contact with the light emitting diode chip 302.

FIG. 16 illustrates a light emitting diode package structure 1618 according to an embodiment. Differences between the light emitting diode package structure 1618 and the light emitting diode package structure 1518 shown in FIG. 15 are disclosed as following. The light emitting diode package structure 1618 further comprises the structural element 628 disposed on the wavelength converting layer 724 and the reflective wall 326, for packaging or protecting the wavelength converting layer 724 from a foreign substance that would cause a damage effect, such as moisture, oxygen gas, etc. In embodiments, the structural element 628 may a barrier film and/or a silicon titanium oxide disposed on the surface of the wavelength converting layer 724 to avoid the foreign substance such as moisture, oxygen gas, etc. The silicon titanium oxide may comprise a glass material such as SiTiO₄, etc., having a light transmissive characteristic and an antioxidative property, and may be disposed on the surface of the wavelength converting layer 724 and a surface of the reflective wall 326 by a coating method or a sticking method as a film. The barrier film may comprise an inorganic material, such as a metal/metalloid oxide (such as SiO₂, Al₂O₃, etc.) or a metal/metalloid nitride (such as Si₃N₃, etc.). The barrier film may be a multi-layer barrier film disposed on the surface of the wavelength converting layer 724 by a coating method or a sticking method as a film.

In embodiments, the light emitting diode package structure 1518 or 1618 is for emitting a white light. In this example, the light emitting diode chip 302 may be a blue light emitting diode chip. The wavelength converting layer 724 may comprise the red all-inorganic perovskite quantum dot CsPb(Br_{1-b}I_{b})₃ and the yellow phosphor powder YAG:Ce. The red all-inorganic perovskite quantum dot complies with 0.5≦b≦1; and/or has the particle diameter in a range of about 10 nm to 14 nm.

In embodiments, the light emitting diode package structure 1518 or 1618 is for emitting a white light. In this example, the light emitting diode chip 302 may be a blue light emitting diode chip. The wavelength converting layer 724 may comprise the green all-inorganic perovskite quantum dot CsPb(Br_{1-b}I_{b})₃ and the red all-inorganic perovskite quantum dot CsPb(Br_{1-b}I_{b})₃. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm.

In embodiments, the light emitting diode package structure 1518 or 1618 is for emitting a white light. In this example, the light emitting diode chip 302 may be a UV light emitting diode chip. The wavelength converting layer 724 may comprise the blue all-inorganic perovskite quantum dot CsPb(ClₐBr₁₋ₐ)₃, the green all-inorganic perovskite quantum dot CsPb(Br_{1-b}I_{b})₃, the red all-inorganic perovskite quantum dot CsPb(Br_{1-b}I_{b})₃. Additionally/optionally, the blue all-inorganic perovskite quantum dot complies with 0<a≦1. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the blue all-inorganic perovskite quantum dot has the particle diameter in a range of about 7 nm to 10 nm. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm.

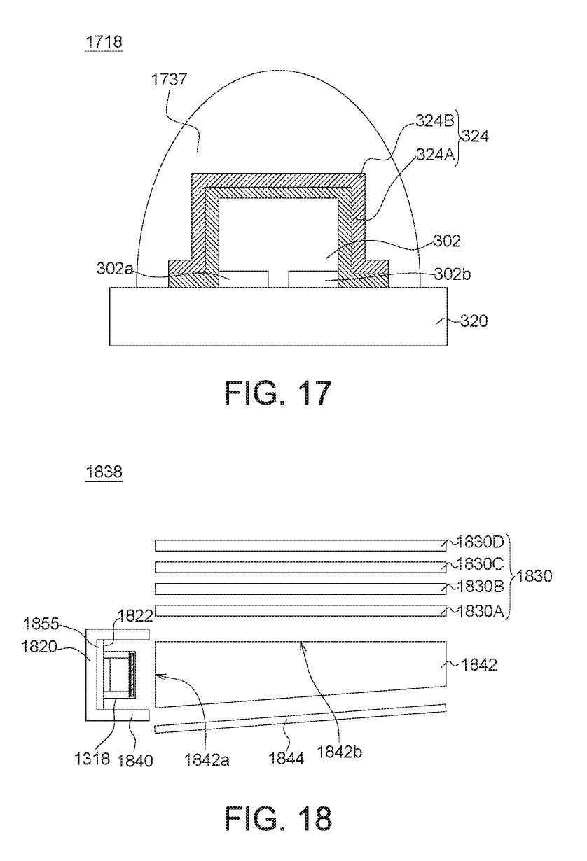

FIG. 17 illustrates a light emitting diode package structure 1718 according to an embodiment. The light emitting diode package structure 1718 comprises the base 320, the light emitting diode chip 302, the wavelength converting layer 324 and a transparent gel 1737. The light emitting diode chip 302 is electrically connected to the base 320 by a flip chip method. The wavelength converting layer 324 is disposed on the upper surface and the side surface of the light emitting diode chip 302, and may be extended onto the upper surface of the base 320. In an embodiment, for example, the first wavelength converting layer 324A comprises the red all-inorganic perovskite quantum dot CsPb(Br_{1-b}I_{b})₃, for emitting a light having a wave peak at a wavelength position of about 570 nm to 700 nm. The second wavelength converting layer 324B comprises the green all-inorganic perovskite quantum dot CsPb(Br_{1-b}I_{b})₃, for emitting a light having a wave peak at a wavelength position of about 500 nm to 570 nm. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm. However, the present disclosure is not limited thereto. The transparent gel 1737 may be used as an encapsulating compound to cover the wavelength converting layer 324 and the base 320.

FIG. 18 illustrates a side type back light module 1838 according to an embodiment. The side type back light module 1838 comprises a frame 1820, a light source 1822, a light guide plate 1842. The light source 1822 comprises a circuit board 1855 on the frame 1820, and a plurality of the light emitting diode package structures 1318 as illustrated with FIG. 13 on the circuit board 1855. The light emitting surface of the light emitting diode package structure 1318 faces toward a light incident surface 1842a of the light guide plate 1842. The frame 1820 comprises a reflective sheet 1840. The reflective sheet 1840 can help focusing a light emitted from the light emitting diode package structure 1318 toward the light guide plate 1842. The light emitted from a light emitting surface 1842b of the light guide plate 1842 goes upward an optical layer 1830 (or a display panel). For example, the optical layer 1830 may comprise an optical layer 1830A, an optical layer 1830B, an optical layer 1830C, and an optical layer 1830D. For example, the optical layer 1830A and the optical layer 1830D may be diffusion sheets. The optical layer 1830B and the optical layer 1830C may be brightness-enhancement sheets. A reflective sheet 1844 may be disposed under the light guide plate 1842 to direct a light upward to the optical layer 1830A, the optical layer 1830B, the optical layer 1830C, the optical layer 1830D (or a display panel, not shown). In embodiments, the side type back light module is not limited to using the light emitting diode package structure 1318 in FIG. 13. The light emitting diode package structure disclosed in other embodiments may be used.

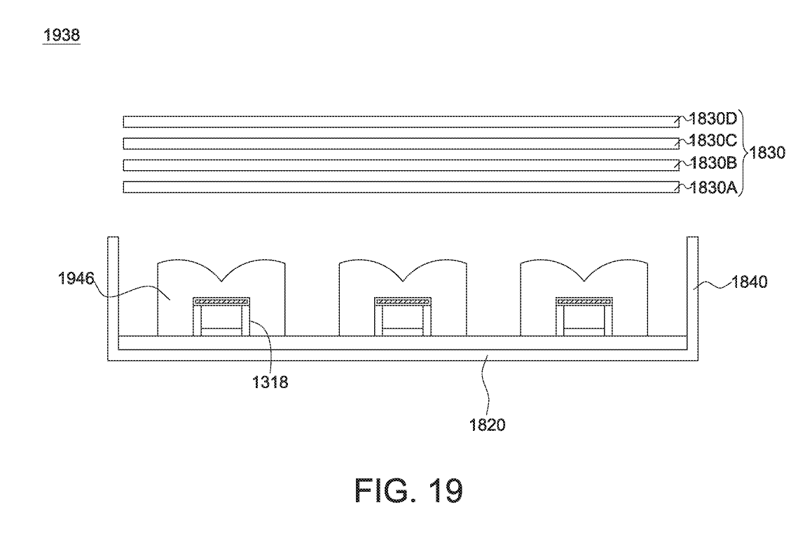

FIG. 19 illustrates a direct type back light module 1938 according to an embodiment. The direct type back light module 1938 comprises a secondary optical element 1946 on the light emitting diode package structure 1318. The light emitting surface of the light emitting diode package structure 1318 faces toward the optical layer 1830. The reflective sheet 1840 can help focusing a light emitted from the light emitting diode package structure 1318 toward the optical layer 1830 (or a display panel). In embodiments, the direct type back light module is not limited to using the light emitting diode package structure 1318 shown in FIG. 13. The light emitting diode package structure disclosed in other embodiments may be used.

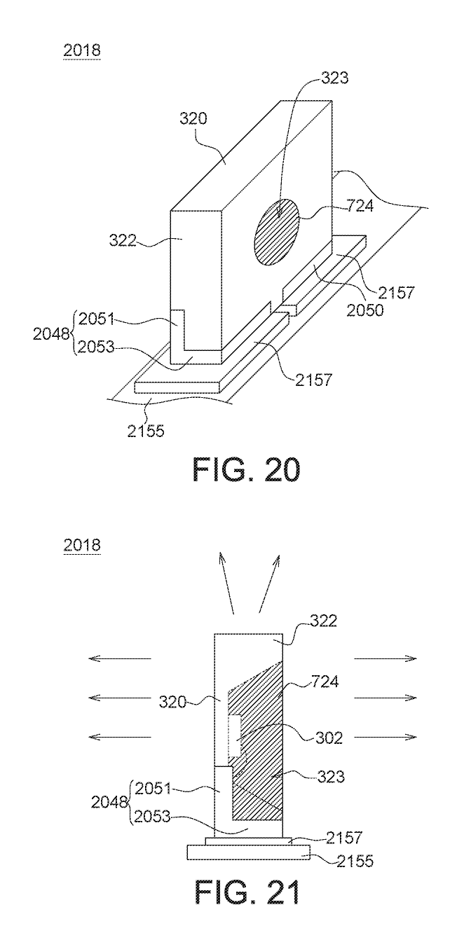

FIG. 20 and FIG. 21 illustrate a three dimensional view and a perspective view of a light emitting diode package structure 2018 according to an embodiment respectively. The light emitting diode package structure 2018 comprises a first electrode 2048 and a second electrode 2050 for electrically connecting to an external component, such as being connected to a connecting pad 2157 of a circuit board 2155. As shown in the figure, the first electrode 2048 and the second electrode 2050 have L shape. A standing portion 2051 of the first electrode 2048 and the second electrode 2050 is on a bottom of the base 320 and exposed by the base 320. A lateral portion 2053 connecting with the standing portion 2051 is embedded in the wall 322 and exposed by the wall 322. A positive electrode and a negative electrode of the light emitting diode chip 302 may be electrically connected to the standing portions 2051 of the first electrode 2048 and the second electrode 2050 through a wire bonding. The wavelength converting layer 724 is filled into the receiving space 323 defined by the base 320 and the wall 322.

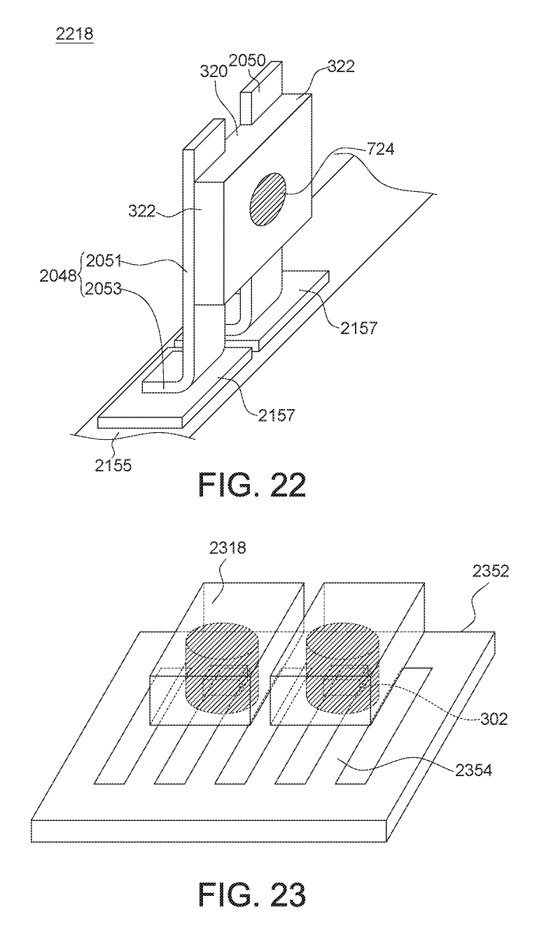

FIG. 22 illustrates a three dimensional view of a light emitting diode package structure 2218 according to an embodiment. The light emitting diode package structure 2218 is different from the light emitting diode package structure 2018 shown in FIG. 20, FIG. 21 in that the standing portion 2051 of the first electrode 2048 and the second electrode 2050 having L shape is extended beyond the base 320 and the wall 322. In addition, the lateral portion 2053 connecting with the standing portion 2051 is extended toward a direction back to the wall 322 and electrically connected to the connecting pad 2157 of the circuit board 2155.

In some embodiments, the base 320 and the wall 322 of the light emitting diode package structure 2018 shown in FIG. 20 and FIG. 21, the light emitting diode package structure 2218 of FIG. 22, is formed by the transparent material. Therefore, a light emitted from the light emitting diode chip 302 can goes out the light emitting diode package structure 2018, 2218 though a light emitting surface directly (without being blocked by an opaque material or reflected by a reflective material). For example, the light may be emitted along a direction perpendicular to the base 320 and out from a upper surface and a lower surface of the light emitting diode package structure 2018, 2218 with a wide angle (of larger than 180 degrees for example).

FIG. 23 to FIG. 26 illustrate a manufacturing method for a light emitting device according to an embodiment.

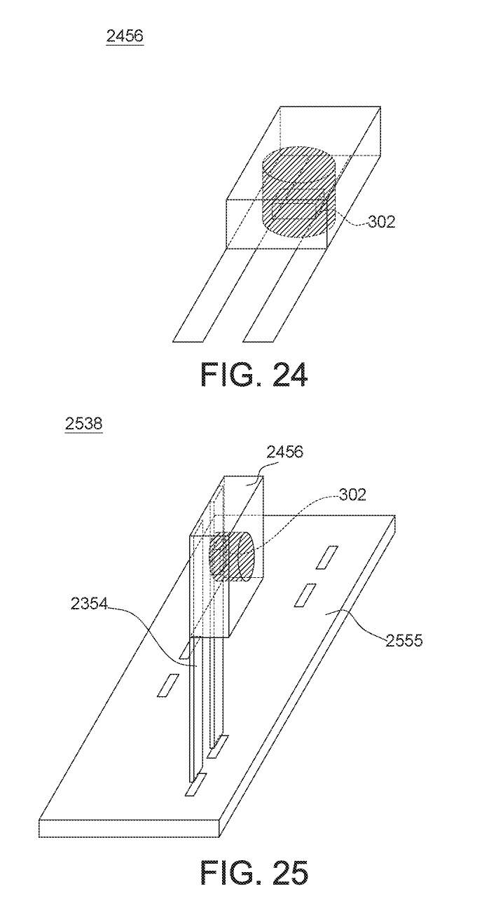

Referring to FIG. 23, a conductive plate 2352 is patterned to form conductive strips 2354 separated from each other. The conductive plate 2352 may be patterned by a method comprising an etching method. Next, a light emitting diode package structure 2318 is disposed on the conductive plate 2352, with a first electrode and a second electrode (not shown) of the light emitting diode package structure 2318 corresponding to the conductive strips 2354 thereby electrically connecting the light emitting diode package structure 2318 to the conductive plate 2352. In an embodiment, the first electrode and the second electrode may be connected to the different conductive strips 2354 spaced apart from each other by a reflow process. Then, the conductive plate 2352 is cut to form a plug-in light emitting unit 2456 as show in FIG. 24. In an embodiment, the cutting step may comprise a punch method.

Referring to FIG. 25, then the plug-in light emitting unit 2456 is inserted on the circuit board 2555 to form a light emitting device 2538 having a light bar structure. The plug-in light emitting unit 2456 may be electrically connected to the circuit board 2555 through the conductive strips 2354 used as the first electrode and the second electrode. In an embodiment, the circuit board 2555 comprises a driving circuit for providing an electric power required by the plug-in light emitting unit 2456 to word.

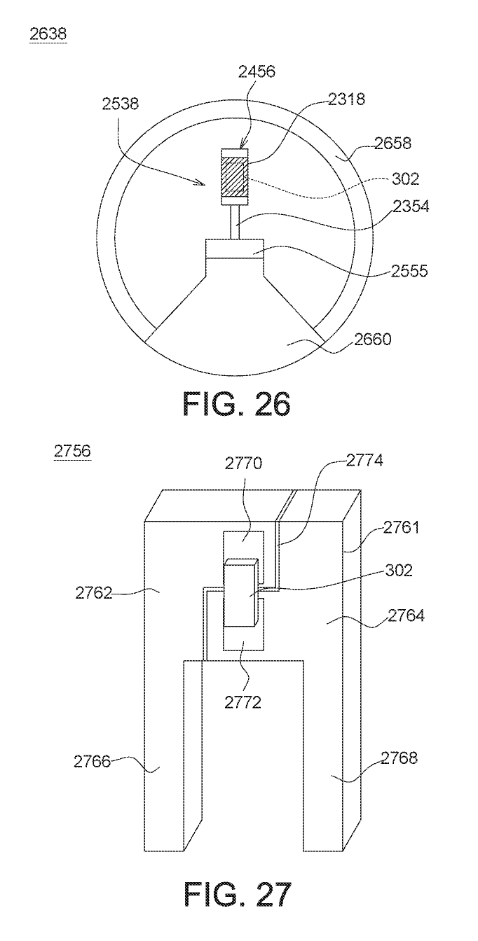

Referring to FIG. 26, the light emitting device 2538 having a light bar structure is disposed on a heat dispersion 2660, and a lamp casing 2658 is disposed to cover the light emitting device 2538, to form a light emitting device 2638 having a tube lamp structure.

In embodiments, for example, the light emitting diode package structure 318, 418, 518, 618, 718, 818, 918, 1018, 1118, 1218, 1318, 1418, 1518, 1618, 1718 as illustrated with FIG. 3 to FIG. 17 may be applied for the light emitting diode package structure 2318. In some embodiments, the light emitting diode package structure 2318 uses the light emitting diode package structure 318, 418, 518, 618, 718, 818 in FIG. 3 to FIG. 8, with the base 320 and the wall 322 formed by the transparent material. Therefore, a light emitted from the light emitting diode chip 302 can goes out the light emitting diode package structure 318, 418, 518, 618, 718, 818, 2318 though a light emitting surface directly (without being blocked by an opaque material or reflected by a reflective material). For example, the light may be emitted along a direction perpendicular to the base 320 and out from a upper surface and a lower surface of the light emitting diode package structure 318, 418, 518, 618, 718, 818, 2318 with a wide angle (of larger than 180 degrees for example).

In embodiments, the light emitting diode package structure 2318/plug-in light emitting unit 2456 is for emitting a white light. In this example, the light emitting diode chip 302 may be a blue light emitting diode chip. The wavelength-converting material may comprise the red all-inorganic perovskite quantum dot CsPb(Br_{1-b}I_{b})₃ and the yellow phosphor powder YAG:Ce. The red all-inorganic perovskite quantum dot complies with 0.5≦b≦1; and/or has the particle diameter in a range of about 10 nm to 14 nm.

In embodiments, the light emitting diode package structure 2318/plug-in light emitting unit 2456 is for emitting a white light. In this example, the light emitting diode chip 302 may be a blue light emitting diode chip. The wavelength-converting material may comprise the green all-inorganic perovskite quantum dot CsPb(Br_{1-b}I_{b})₃ and the red all-inorganic perovskite quantum dot CsPb(Br_{1-b}I_{b})₃. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm.

In embodiments, the light emitting diode package structure 2318/plug-in light emitting unit 2456 is for emitting a white light. In this example, the light emitting diode chip 302 may be a UV light emitting diode chip. The wavelength-converting material may comprise the blue all-inorganic perovskite quantum dot CsPb(ClₐBr₁₋ₐ)₃, the green all-inorganic perovskite quantum dot CsPb(Br_{1-b}I_{b})₃, the red all-inorganic perovskite quantum dot CsPb(Br_{1-b}I_{b})₃. Additionally/optionally, the blue all-inorganic perovskite quantum dot complies with 0<a≦1. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the blue all-inorganic perovskite quantum dot has the particle diameter in a range of about 7 nm to 10 nm. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm.

FIG. 27 illustrates a plug-in light emitting unit 2756 according to an embodiment. The plug-in light emitting unit 2756 comprises the light emitting diode chip 302, a base 2761, a first electrode inserting foot 2766 and a second electrode inserting foot 2768. The base 2761 comprises a first base plate 2762, a second base plate 2764 and an insulating layer 2774. The insulating layer 2774 is disposed between the first base plate 2762 and the second base plate 2764 to electrically insulate the first base plate 2762 from the second base plate 2764. The light emitting diode chip 302 is disposed on a die bonding region contained in the base 2761 used as a die bonding plate. The light emitting diode chip 302 crossing the insulating layer 2774 is disposed on the first base plate 2762 and the second base plate 2764 by a flip chip method. A positive electrode and a negative electrode of the light emitting diode chip 302 is electrically connected to a first contact pad 2770 and a second contact pad 2772 of the first base plate 2762 and the second base plate 2764 so as to electrically connect to the first electrode inserting foot 2766 and the second electrode inserting foot 2768 extended from the first base plate 2762 and the second base plate 2764 respectively. The light emitting diode chip 302 may be electrically connected to the first contact pad 2770 and the second contact pad 2772 through a solder (not shown).

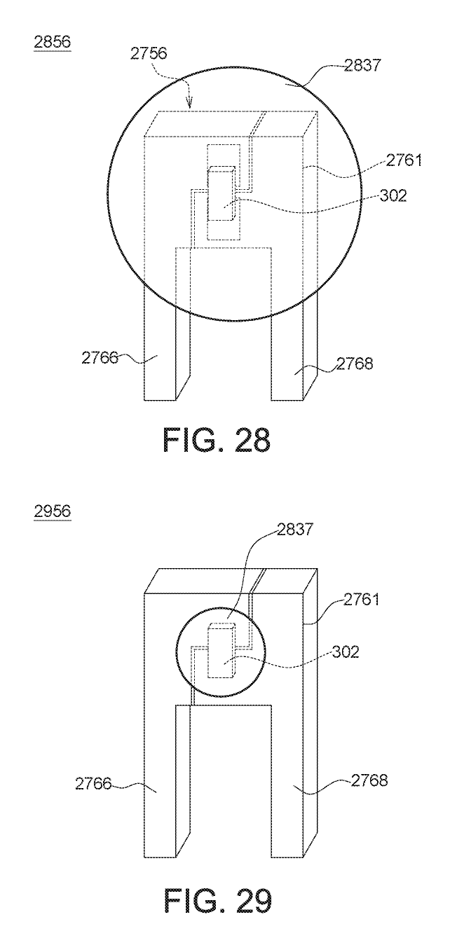

FIG. 28 illustrates a plug-in light emitting unit 2856 according to another embodiment. The plug-in light emitting unit 2856 comprises a transparent gel 2837 and the plug-in light emitting unit 2756 as illustrated with FIG. 27. The transparent gel 2837 covers the whole of the light emitting diode chip 302 and the base 2761, and covers a portion of the first electrode inserting foot 2766 and the second electrode inserting foot 2768.

FIG. 29 illustrates a plug-in light emitting unit 2956 according to another embodiment. The plug-in light emitting unit 2956 is different from the plug-in light emitting unit 2856 shown in FIG. 28 in that the transparent gel 2837 covers the whole of the light emitting diode chip 302, covers a portion of a surface of the base 2761 having the light emitting diode chip 302 thereon, but not covers the first electrode inserting foot 2766 and the second electrode inserting foot 2768.

In embodiments, the plug-in light emitting unit 2856 or 2956 may comprise the wavelength-converting material doped in the transparent gel 2837, or may comprise the wavelength converting layer comprising the wavelength-converting material and disposed on the surface of the light emitting diode chip 302. In embodiments, the transparent gel 2837 may comprise any suitable transparent polymer material, such as, PMMA, PET, PEN, PS, PP, PA, PC, PI, PDMS, epoxy, silicone or other suitable materials, or a combination thereof. The transparent gel 2837 may be doped with other substances to vary an emitting light property according to actual demands. For example, the diffusion particles may be doped into the transparent gel 2837 to change a path of an emitting light. The diffusion particles may comprise TiO₂, SiO₂, Al₂O₃, BN, ZnO, etc., and/or have the same particle diameter or different particle diameters.

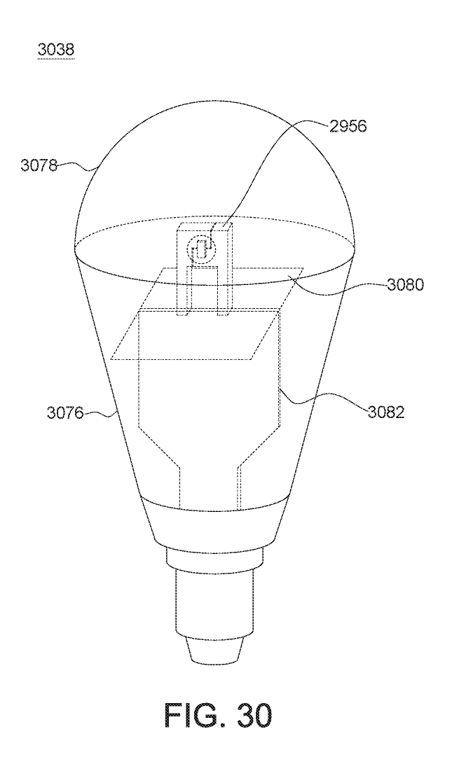

FIG. 30 illustrates a light emitting device 3038 according to an embodiment. The light emitting device 3038 having a bulb lamp structure comprises the plug-in light emitting unit 2956 as shown in FIG. 29, a casing body 3076, a transparent lamp cover 3078 and a circuit board 3080. The plug-in light emitting unit 2956 is inserted into the circuit board 3080 and electrically connected to the circuit board 3080 so as to electrically connect to a driving circuit 3082 of the circuit board 3080. The plug-in light emitting unit 2956 is disposed together with the circuit board 3080 in a receiving space defined by the casing body 3076 and the transparent lamp cover 3078 connecting with the casing body 3076.

The transparent gel illustrated in the present disclosure may comprise any suitable transparent polymer material, such as, PMMA, PET, PEN, PS, PP, PA, PC, PI, PDMS, epoxy, silicone or other suitable materials, or a combination thereof.

The transparent gel may be doped with other substances to vary an emitting light property according to actual demands. For example, the diffusion particles may be doped into the transparent gel to change a path of an emitting light. The diffusion particles may comprise TiO₂, SiO₂, Al₂O₃, BN, ZnO, etc., and/or have the same particle diameter or different particle diameters.

The light emitting device in the present disclosure is not limited to the foregoing embodiments, and may comprise other kinds of the light emitting diode package structures, may be applied for a light emitting module of the display device such as a back light module or a front light module, or a lighting device such as a tube lamp, a bulb lamp, or may have other types of structures.

The light emitting diode package structure of a single unit is not limited to only the light emitting diode chip of a single, and may use the light emitting diode chips of two or more units for emitting lights of the same color/wavelength or different colors/wavelengths.

In embodiments, the light emitting diode package structure 2018, 2218 and the plug-in light emitting unit 2856, 2956 are for emitting a white light. In this example, the light emitting diode chip 302 may be a blue light emitting diode chip. The wavelength-converting material may comprise the red all-inorganic perovskite quantum dot CsPb(Br_{1-b}I_{b})₃ and the yellow phosphor powder YAG:Ce. The red all-inorganic perovskite quantum dot complies with 0.5≦b≦1; and/or has the particle diameter in a range of about 10 nm to 14 nm.

In embodiments, the light emitting diode package structure 2018, 2218 and the plug-in light emitting unit 2856, 2956 are for emitting a white light. In this example, the light emitting diode chip 302 may be a blue light emitting diode chip. The wavelength-converting material may comprise the green all-inorganic perovskite quantum dot CsPb(Br_{1-b}I_{b})₃ and the red all-inorganic perovskite quantum dot CsPb(Br_{1-b}I_{b})₃. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm.

In embodiments, the light emitting diode package structure 2018, 2218 and the plug-in light emitting unit 2856, 2956 are for emitting a white light. In this example, the light emitting diode chip 302 may be a UV light emitting diode chip. The wavelength-converting material may comprise the blue all-inorganic perovskite quantum dot CsPb(ClₐBr₁₋ₐ)₃, the green all-inorganic perovskite quantum dot CsPb(Br_{1-b}I_{b})₃, the red all-inorganic perovskite quantum dot CsPb(Br_{1-b}I_{b})₃. Additionally/optionally, the blue all-inorganic perovskite quantum dot complies with 0<a≦1. Additionally/optionally, the green all-inorganic perovskite quantum dot complies with 0≦b<0.5. Additionally/optionally, the red all-inorganic perovskite quantum dot complies with 0.5≦b≦1. Additionally/optionally, the blue all-inorganic perovskite quantum dot has the particle diameter in a range of about 7 nm to 10 nm. Additionally/optionally, the green all-inorganic perovskite quantum dot has the particle diameter in a range of about 8 nm to 12 nm. Additionally/optionally, the red all-inorganic perovskite quantum dot has the particle diameter in a range of about 10 nm to 14 nm.

In embodiments, the wavelength-converting material comprising the all-inorganic perovskite quantum dot may be applied to a light emitting device of a micro-size, such as a micro-light emitting diode (Micro LED) smaller than a conventional light emitting diode in size.

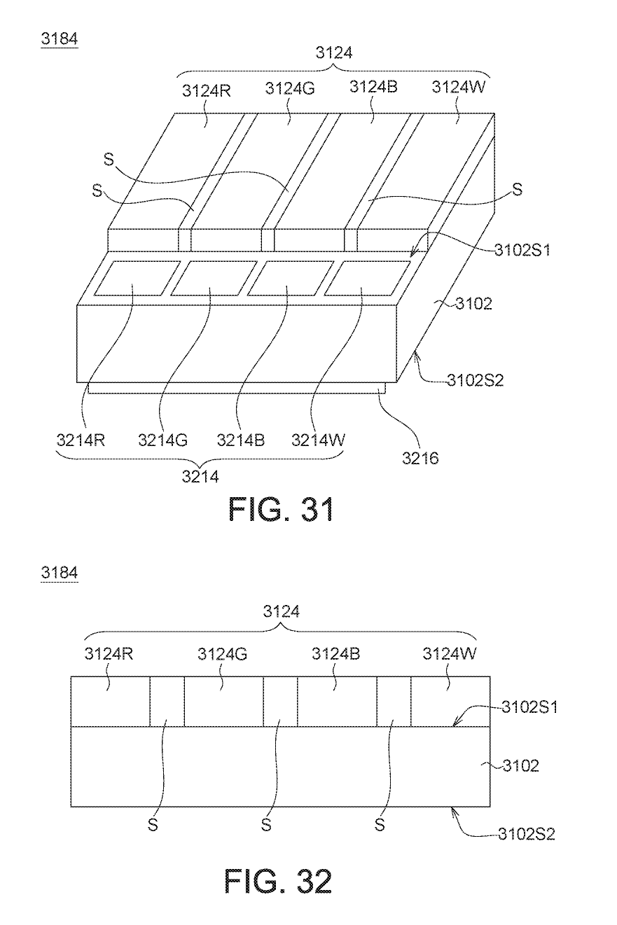

For example, FIG. 31 and FIG. 32 illustrate a three dimensional view and a cross-section view of a light emitting device 3184 according to an embodiment respectively. In embodiments, the light emitting device 3184 may be a micro-light emitting diode device, comprising a light emitting diode chip 3102, wavelength converting layers 3124 and spacing layers S. The light emitting diode chip 3102 comprises opposing surface 3102S1 and surface 3102S2. The surface 3102S1 is a light emitting surface of the light emitting diode chip 3102. The wavelength converting layers 3124 is on a light emitting side of the light emitting diode chip 3102. The wavelength converting layers 3124 is spaced apart from each other and disposed on the surface 3102S1 of the light emitting diode chip 3102. The spacing layers S on the surface 3102S1 of the light emitting diode chip 3102 is disposed between the wavelength converting layers 3124 separately.

In an embodiment, the light emitting diode chip 3102 may be a vertical light emitting diode chip, comprising a first electrode 3214 and a second electrode 3216 on the surface 3102S1 and the surface 3102S2, respectively. The light emitting side of the light emitting diode chip 3102 and the first electrode 3214 are on the same side of the light emitting device 3184.

In an embodiment, the wavelength converting layers 3124 comprise at least a wavelength converting layer 3124R, a wavelength converting layer 3124G, a wavelength converting layer 3124B. The wavelength converting layer 3124R can be excited by the light emitting diode chip 3102 to emit a red light. The wavelength converting layer 3124G can be excited by the light emitting diode chip 3102 to emit a green light. The wavelength converting layer 3124B can be excited by the light emitting diode chip 3102 to emit a blue light. This configuration may be used as a pixel for application in a display, with the distinct wavelength converting layers 3124 as distinct sub pixels. In other words, the wavelength converting layer 3124R corresponds to a red sub pixel. The wavelength converting layer 3124G corresponds to a green sub pixel. In addition, the wavelength converting layer 3124B corresponds to a blue sub pixel.

In embodiments, the wavelength converting layers 3124 may further comprise a wavelength converting layer 3124W corresponding to a white sub pixel. The wavelength converting layer 3124W may be separated from the wavelength converting layers 3124R, 3124G, 3124B by the spacing layers S and disposed on the surface 3102S1 of the light emitting diode chip 3102.

The pixel comprises at least the red sub pixel, the green sub pixel and the blue sub pixel. The pixel may further comprise the white sub pixel according to designs. A plurality of the pixels or the sub pixels may be arranged in an array design.

In embodiments, spacing layers S may comprise a material comprising a light absorbing material or/and a reflective material, avoiding affection between lights of the sub pixels of different colors to improve display effect of a display. For example, the light absorbing material may comprise a black gel, etc., or a combination thereof. For example, the reflective material may comprise a white gel, etc., or a combination thereof.

Moreover, the first electrode 3214 may comprise a first electrode 3214R, a first electrode 3214G, a first electrode 3214B, and a first electrode 3214W, corresponding to the red sub pixel, the green sub pixel, the blue sub pixel and the white sub pixel, respectively. The second electrode 3216 may be a common electrode of the red sub pixel, the green sub pixel, the blue sub pixel and the white sub pixel. In other embodiments, electrodes separated from each other corresponding to the sub pixels of different colors, similar with the first electrodes 3214, may be used. The sub pixels of different colors may be independently controlled by the distinct corresponding electrodes to be addressed or derived to emit a light.

In embodiments, for example, the light emitting diode chip 3102 may be a UV light emitting diode chip for emitting the first light having a wavelength of about 200 nm to 400 nm. Otherwise, the light emitting diode chip 3102 may be a blue light emitting diode chip for emitting the first light having a wavelength of about 430 nm to 480 nm.

In embodiments, the wavelength-converting material of the wavelength converting layer 3124R corresponding to the red sub pixel may comprise the red all-inorganic perovskite quantum dot CsPb(Br_{1-b}I_{b})₃, complying with 0.5≦b≦1, and/or having the particle diameter in a range of about 10 nm to 14 nm. The wavelength-converting material of the wavelength converting layer 3124G corresponding to the green sub pixel may comprise the green all-inorganic perovskite quantum dot CsPb(Br_{1-b}I_{b})₃, complying with 0≦b<0.5, and/or having the particle diameter in a range of about 8 nm to 12 nm. The wavelength-converting material of the wavelength converting layer 3124B corresponding to the blue sub pixel may comprise the blue all-inorganic perovskite quantum dot CsPb(ClₐBr₁₋ₐ)₃, complying with 0<a≦1, and/or having the particle diameter in a range of about 7 nm to 10 nm; and/or a blue phosphor powder. The wavelength-converting material may be doped in the transparent material.

In an example of the light emitting diode chip 3102 being the blue light emitting diode chip, the wavelength converting layer 3124B corresponding to the blue sub pixel may be a transparent material, so that a blue light emitted from the blue sub pixel is directly provided by the light emitting diode chip 3102. The wavelength converting layer 3124W corresponding to the white sub pixel may comprise the yellow phosphor powder, such as YAG:Ce, capable of emitting a yellow light by being excited by a portion of the first light (blue light having a wavelength of about 430 nm to 480 nm) emitted from the light emitting diode chip 3102, and the yellow light is mixed with the remained blue light to form an emitting white light.

In embodiments, the micro light emitting diode as shown in FIG. 31 and FIG. 32 may be applied to a micro-light emitting diode display (Micro LED display). Comparing to a conventional light emitting diode technique, the micro light emitting diode has a smaller size, and a gap distance between adjacent two pixels can be reduced from a size grade of millimeter to a size grade of micrometer. Therefore, it is possible to form an array of light emitting diodes of high density and small feature on a single integrated circuit chip. It is easier to control a color precisely. A device can have advantages of a longer lifespan, a higher brightness, a stable material stability or lifespan, a less image sticking, etc., with using advantages of the light emitting diode such as high efficiency, high brightness, high reliability and fast response time, etc. A self-light emitting device without using a back light source can have advantages of saving energy, simple construction, small volume, thin module, etc. In addition, using a micro light emitting diode technique can achieve a high resolution.

The present disclosure may be better understood by reference to the following embodiments.

[Manufacturing all-Inorganic Perovskite Quantum]

Cs₂CO₃ of 0.814 g, octadecene (ODE) of 40 mL and oleic acid (OA) of 2.5 mL were put in a three-necked bottle of 100 mL, and a dewatering step was performed thereto in a condition of vacuum and 120° C. for one hour. Then, the three-necked bottle was heated to 150° C. in a nitrogen gas system until the Cs₂CO₃ and the oleic acid reacted completely so as to obtain a Cs precursor (Cs-Oleate precursor).

Next, ODE of 5 mL and PbX2 of 0.188 mmol (with X=Cl, Br or I, or a combination thereof, decided according to a halogen element contained in the all-inorganic perovskite quantum dot) were put in a three-necked bottle of 25 mL, and a dewatering step was performed thereto in a condition of vacuum and 120° C. for one hour. Then oleylamine of 0.5 mL and OA of 0.5 mL were injected into the three-necked bottle. After the solution became limpid, a heating temperature was increased to 140-200° C. (decided to adjust a particle size of the all-inorganic perovskite quantum dot). Then the Cs-Oleate precursor of 0.4 mL was rapidly injected into the three-necked bottle. After waiting 5 seconds, the reaction system was cooled by in a chilled-water bath. Then a centrifugal purification is performed so as to get the all-inorganic perovskite quantum dot CsPb(ClₐBr_{1-a-b}I_{b})₃.

[Red/Green all-Inorganic Perovskite Quantum Dot CsPb(Br_{1-b}I_{b})₃]

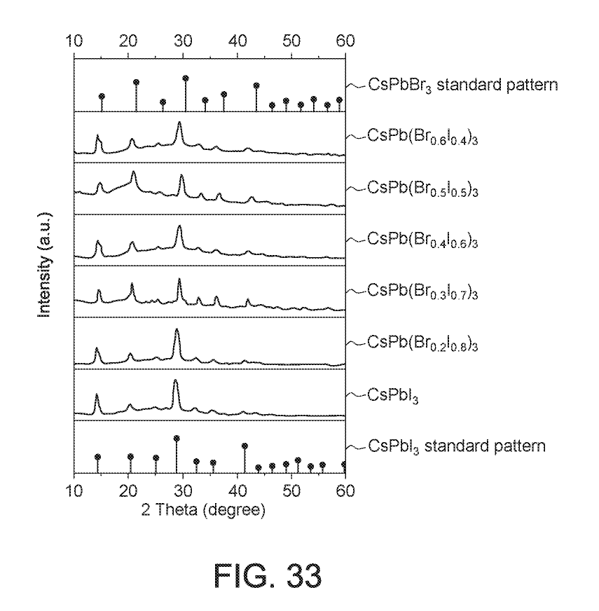

FIG. 33 shows X-ray diffraction patterns of the all-inorganic perovskite quantum dots of CsPb(Br_{1-b}I_{b})₃ according to embodiments. The XRD patterns from the bottom to the top in FIG. 33 in order correspond to CsPbI₃, CsPb(Br_{0.2}I_{0.8})₃, CsPb(Br_{0.3}I_{0.7})₃, CsPb(Br_{0.4}I_{0.6})₃, CsPb(Br_{0.5}I_{0.5})₃, CsPb(Br_{0.6}I_{0.4})₃, nucleation temperatures of which are all 180° C. From comparison of the XRD patterns of the synthesized perovskite quantum dots with the various Br and I ratios and the standard XRD patterns of CsPbI₃ and CsPbBr₃ of cubic phase, it could be found that all of the peak positions of the synthesized all-inorganic perovskite quantum dot CsPb(Br_{1-b}I_{b})₃ are identical to the standard patterns of cubic phase, indicating that the synthesized all-inorganic perovskite quantum dot CsPb(Br_{1-b}I_{b})₃ all have a cubic phase.

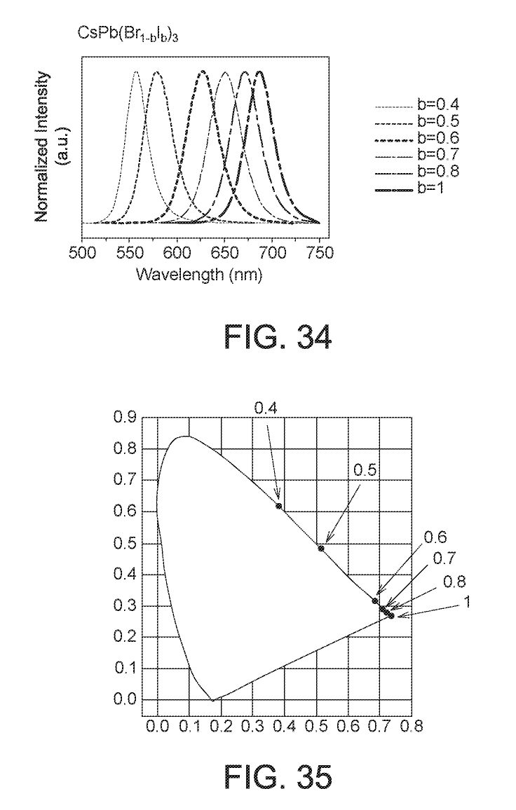

FIG. 34 shows normalized photoluminescence (PL) spectrums of the all-inorganic perovskite quantum dots CsPb(Br_{1-b}I_{b})₃, excited by an emitting light of 460 nm. Data of peak position (position of the strongest intensity) and full width at half maximum (FWHM) are listed in Table 1. FIG. 35 shows positions of the all-inorganic perovskite quantum dots CsPb(Br_{1-b}I_{b})₃ in a CIE diagram.

TABLE 1
All-inorganic perovskite quantum dot CsPb(Br_{1-b}I_{b})₃

| | peak position | FWHM |
|---|---|---|
| b | (nm) | (nm) |
| 0.4 | 557 | 27 |
| 0.5 | 578 | 35 |
| 0.6 | 625 | 37 |
| 0.7 | 650 | 40 |
| 0.8 | 670 | 37 |
| 1 | 687 | 35 |

From the results of FIG. 34, FIG. 35 and Table 1, it is found that the all-inorganic perovskite quantum dots CsPb(Br_{1-b}I_{b})₃ have a red shift effect (i.e. shifting of peak position from 557 nm to 687 nm gradually) with a change of increasing the I element content and decreasing the Br element content, i.e. b increased from 0.4 to 1. The phenomenon could by explained with a quantum confinement effect. In other words, the red shift of the emission spectrum of the all-inorganic perovskite quantum dots CsPb(Br_{1-b}I_{b})₃ are resulted from an enlarging material size as the I element content is increased since a diameter of a I ion is bigger than a diameter of a Br ion.

The all-inorganic perovskite quantum dots CsPb(Br_{1-b}I_{b})₃ complying with b=0.5-1 are red quantum dots. The red all-inorganic perovskite quantum dot CsPb(Br_{0.4}I_{0.6})₃ has the strongest emission position at 625 nm, complying with the red emission wavelength range in the common market condition. The red all-inorganic perovskite quantum dot CsPb(Br_{0.4}I_{0.6})₃ has the FWHM of 35 nm, narrower than a common commercial red phosphor powder, indicating having a better pure quality of color. Therefore, as the all-inorganic perovskite quantum dot is applied to a light emitting device, an emission efficiency of a product can be increased. Otherwise, when the all-inorganic perovskite quantum dot together with a phosphor material of another kind is applied to a light emitting device, a color rendering of a product can be increased.

Among the all-inorganic perovskite quantum dots CsPb(Br_{1-b}I_{b})₃, the all-inorganic perovskite quantum dot complying with b=0.4 (CsPb(Br_{0.6}I_{0.4})₃) is a green quantum dot. The green all-inorganic perovskite quantum dot CsPb(Br_{0.6}I_{0.4})₃ has the strongest emission position at 557 nm, complying with the green emission wavelength range in the common market condition. The green all-inorganic perovskite quantum dot CsPb(Br_{0.6}I_{0.4})₃ has the FWHM of 27 nm, narrower than a common commercial green phosphor powder, indicating having a better pure quality of color. Therefore, as the all-inorganic perovskite quantum dot is applied to a light emitting device, an emission efficiency of a product can be increased. Otherwise, when the all-inorganic perovskite quantum dot together with a phosphor material of another kind is applied to a light emitting device, a color rendering of a product can be increased.

[All-Inorganic Perovskite Quantum Dot CsPb(ClₐBr₁₋ₐ)₃]

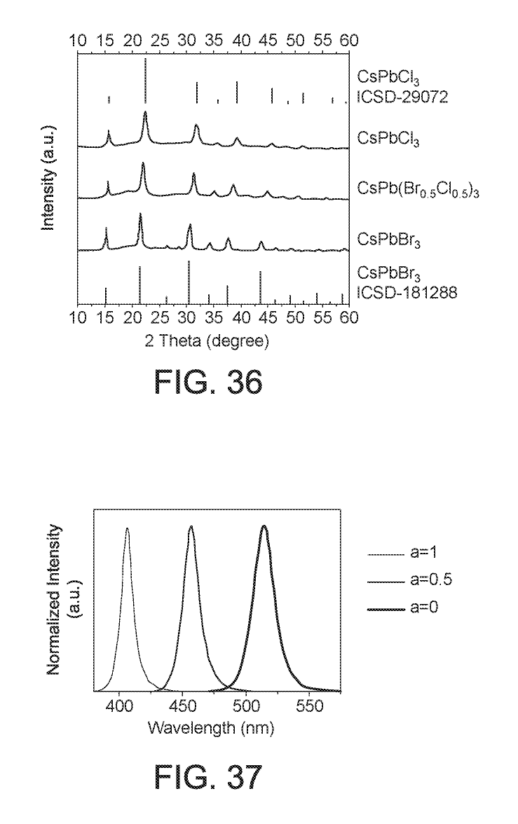

FIG. 36 shows X-ray diffraction patterns of the all-inorganic perovskite quantum dots of CsPb(ClₐBr₁₋ₐ)₃ with a=0, 0.5, 1 according to embodiments. From comparison of the XRD patterns of the synthesized perovskite quantum dots CsPb(ClₐBr₁₋ₐ)₃ and the standard XRD patterns of CsPBr₃ and CsPbCl₃ of cubic phase, it could be found that all of the peak positions of the synthesized all-inorganic perovskite quantum dot CsPb(ClₐBr₁₋ₐ)₃ are identical to the standard patterns of cubic phase, indicating that the synthesized all-inorganic perovskite quantum dot CsPb(ClₐBr₁₋ₐ)₃ all have a cubic phase. Nucleation temperatures of the all-inorganic perovskite quantum dots CsPb(ClₐBr₁₋ₐ)₃ are all 180° C.

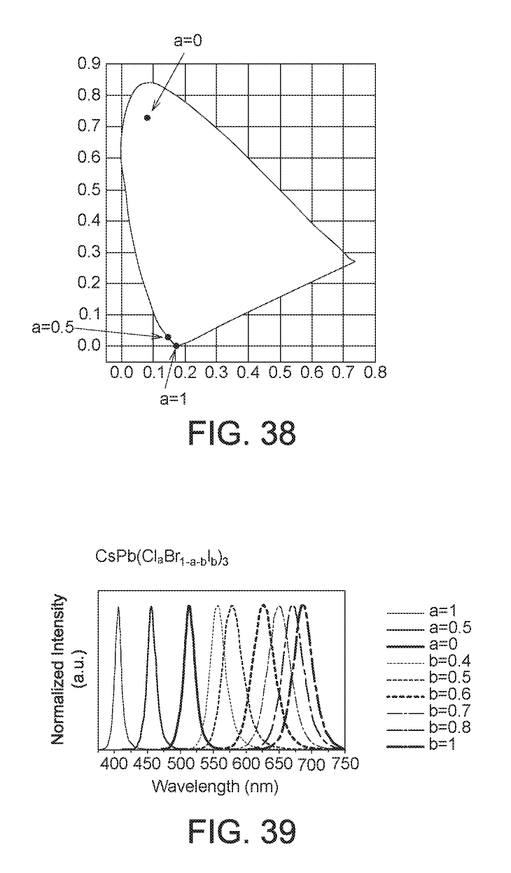

FIG. 37 shows normalized PL spectrums of the all-inorganic perovskite quantum dots of CsPb(ClₐBr₁₋ₐ)₃ (a=0, 0.5, 1) according to embodiments, excited by a light of a wavelength 380 nm. Data of peak position (position of the strongest intensity) and full width at half maximum (FWHM) are listed in Table 2. FIG. 38 shows positions of the all-inorganic perovskite quantum dots CsPb(ClₐBr₁₋ₐ)₃ in a CIE diagram.

TABLE 2
all-inorganic perovskite quantum dot CsPb(ClₐBr₁₋ₐ)₃

| | peak position | FWHM |
|---|---|---|
| a | (nm) | (nm) |
| 0 | 514 | 19 |
| 0.5 | 457 | 15 |
| 1 | 406 | 11 |

From the results of FIG. 37, FIG. 38 and Table 2, it is found that the all-inorganic perovskite quantum dots CsPb(ClₐBr₁₋ₐ)₃ have a red shift effect (i.e. shifting of peak position from 406 nm to 514 nm gradually) with a change of decreasing the Cl element content and increasing the Br element content, i.e. b decreased from 1 to 0. The phenomenon could by explained with a quantum confinement effect. In other words, the red shift of the emission spectrum of the all-inorganic perovskite quantum dots CsPb(ClₐBr₁₋ₐ)₃ are resulted from an enlarging material size as the Cl element content is decreased since a diameter of a Cl ion is smaller than a diameter of a Br ion. Among the all-inorganic perovskite quantum dots CsPb(ClₐBr₁₋ₐ)₃, the all-inorganic perovskite quantum dot complying with a=0 (CsPbBr₃, equivalent to the chemical formula CsPb(Br_{1-b}I_{b})₃ complying with b=1) is a green quantum dot, the all-inorganic perovskite quantum dots complying with a=0.5, 1 (CsPb(Cl_{0.5}Br_{0.5})₃, CsPbCl₃) are blue quantum dots.

FIG. 39 shows normalized PL spectrums combining the normalized PL spectrums of FIG. 34 and FIG. 37. It is shown that the all-inorganic perovskite quantum dots CsPb(ClₐBr_{1-a-b}I_{b})₃ have various light emitting characteristics with different Cl, Br, I contents. The emitting lights contain ranges of red, green and blue, and the FWHM of each is narrow. Therefore, the composition of the all-inorganic perovskite quantum dot can be adjusted accordingly to obtain an emitting light of an expected peak position. A light emitting device using the all-inorganic perovskite quantum dot can exhibit a good optoelectronic property.

### [Light Emitting Diode Package Structure]

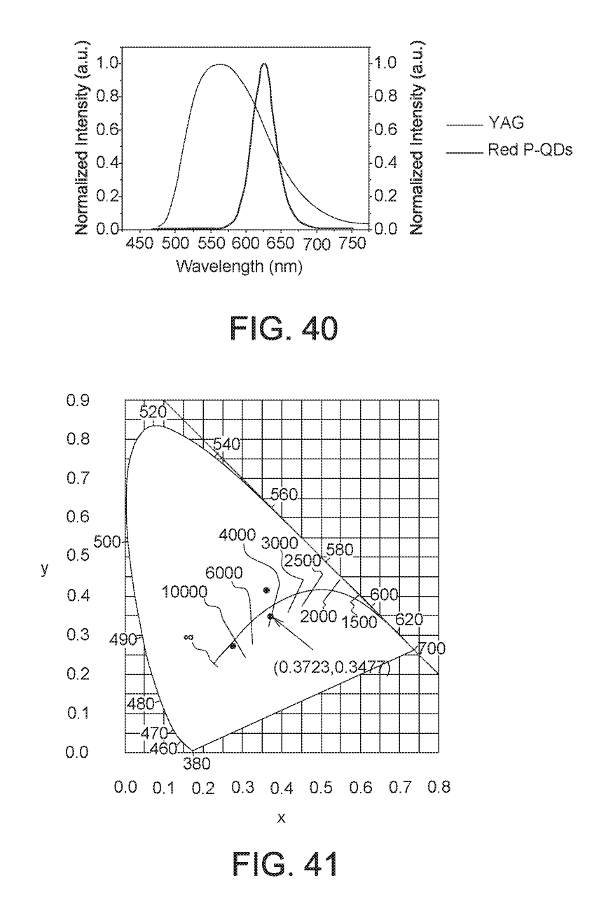

FIG. 40 shows a normalized PL spectrum of a light emitting diode package structure comprising a blue light emitting diode chip with the red all-inorganic perovskite quantum dot of CsPb(Br_{0.4}I_{0.6})₃ together with a commercial yellow phosphor powder YAG:Ce according to an embodiment. The red all-inorganic perovskite quantum dot CsPb(Br_{0.4}I_{0.6})₃ has an emission wavelength of 625 nm. The yellow phosphor powder YAG:Ce has an emission wavelength of 560 nm. FIG. 41 shows a gamut of colors in a CIE diagram of the light emitting diode package structure, similar to a black body radiation, suitable in commercial use. As listed in Table 3, the light emitting diode package structure has a correlated color temperature (CCT) of 4010K corresponding to a warm white color, an emitting efficiency of 56 lm/W, a general color rendering index (CRI Ra) of 83.9, a color rendering R9 of 40. Accordingly, a package product can have an improved color rendering.

TABLE 3

| | emitting | | |
|---|---|---|---|
| CCT | efficiency | | |
| (K) | (lm/W) | Ra | R9 |
| 4010 | 56 | 83.9 | 40 |

[Use of Various Kinds of all-Inorganic Perovskite Quantum Dots]

Table 4 lists conditions and emitting results of Embodiment 1 to Embodiment 5. In each of the embodiments, a light emitting diode chip is used excite a combination of the all-inorganic perovskite quantum dots CsPb(Br_{1-b}I_{b})₃ of various kinds. As shown in Table 4, Embodiment 1 uses the all-inorganic perovskite quantum dot CsPb(Br_{1-b}I_{b})₃ of two kinds, respectively being b=0.3-0.4 and b=0.7-0.8, and exhibits a spectrum having a general color rendering index (Ra) of 40. Embodiment 2 uses the all-inorganic perovskite quantum dot CsPb(Br_{1-b}I_{b})₃ of three kinds, respectively being b=0.1-0.2, b=0.5-0.6 and b=0.6-0.7, and exhibits a spectrum having a Ra of 60. Embodiment 3 uses the all-inorganic perovskite quantum dot CsPb(Br_{1-b}I_{b})₃ of four kinds, respectively being b=0-0.1, b=0.2-0.3, b=0.4-0.5 and b=0.6-0.7, and exhibits a spectrum having a Ra of 75. Embodiment 4 uses the all-inorganic perovskite quantum dot CsPb(Br_{1-b}I_{b})₃ of five kinds, respectively being b=0-0.1, b=0.3-0.4, b=0.5-0.6, b=0.7-0.8 and b=0.8-0.9, and exhibits a spectrum having a Ra of 90. Embodiment 5 uses the all-inorganic perovskite quantum dot CsPb(Br_{1-b}I_{b})₃ of six kinds, respectively being b=0-0.1, b=0.2-0.3, b=0.5-0.6, b=0.6-0.7, b=0.7-0.8 and b=0.9-1, and exhibits a spectrum having a Ra of 95.

TABLE 4

| b | Embodiment 1 | Embodiment 2 | Embodiment 3 | Embodiment 4 | Embodiment 5 |
|---|---|---|---|---|---|
| 0-0.1 | | | | | |
| 0.1-0.2 | | | | | |
| 0.2-0.3 | | | | | |
| 0.3-0.4 | | | | | |
| 0.4-0.5 | | | | | |
| 0.5-0.6 | | | | | |
| 0.6-0.7 | | | | | |
| 0.7-0.8 | | | | | |
| 0.8-0.9 | | | | | |
| 0.9-1 | | | | | |
| CRI | 40 | 60 | 75 | 90 | 95 |

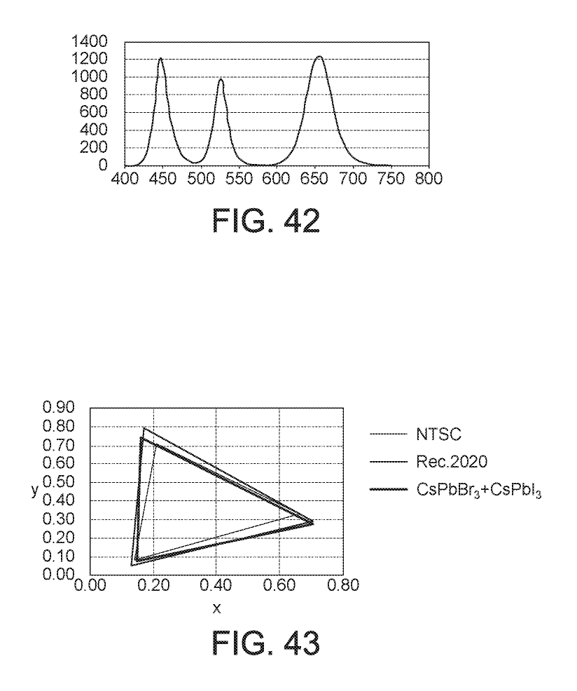

In other embodiments, as shown in FIG. 42 and FIG. 43, respectively showing a PL spectrum and gamuts of colors in a CIE diagram of the all-inorganic perovskite quantum dots of CsPbBr₃ and CsPbI₃ excited by a light emitting diode chip according to embodiments. Using the all-inorganic perovskite quantum dots CsPb(Br_{1-b}I_{b})₃ of at least two kinds of compositions excited by the light emitting diode chip can achieve a NTSC equal to or higher than 90%. For example, a combination of the all-inorganic perovskite quantum dots of two kinds (CsPbBr₃ and CsPbI₃) excited by the light emitting diode chip can achieve a NTSC of 119%.

According to the disclosed embodiments, the all-inorganic perovskite quantum dot having the chemical formula of CsPb(ClₐBr_{1-a-b}I_{b})₃, complying with 0≦a≦1, 0≦b≦1, can exhibit a good property of an emission spectrum having a narrow FWHM and pure quality of color, and can improve an emission effect of a light emitting device as being applied for the light emitting device.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting device, comprising:
a light emitting diode chip; and
a wavelength-converting material being capable of being excited by a first light emitted from the light emitting diode chip to emit a second light having a wavelength different from a wavelength of the first light, the wavelength-converting material comprising an all-inorganic perovskite quantum dot having a chemical formula of CsPb(ClₐBr_{1-a-b}I_{b})₃, wherein 0≦a≦1, 0≦b≦1.

2. The light emitting device according to claim 1, wherein the all-inorganic perovskite quantum dot has a chemical formula of CsPb(Br_{1-b}I_{b})₃, wherein 0.5≦b≦1, all-inorganic perovskite quantum dot is a red quantum dot.

3. The light emitting device according to claim 2, wherein the second light emitted from the red quantum dot has a wave peak of 570 nm to 700 nm, a full width at half maximum (FWHM) of 20 nm to 60 nm.

4. The light emitting device according to claim 1, wherein the all-inorganic perovskite quantum dot has a chemical formula of CsPb(Br_{1-b}I_{b})₃, wherein 0≦b<0.5, all-inorganic perovskite quantum dot is a green quantum dot.

5. The light emitting device according to claim 4, wherein the second light emitted from the green quantum dot has a wave peak of 500 nm to 570 nm, a FWHM of 15 nm to 40 nm.

6. The light emitting device according to claim 1, wherein the all-inorganic perovskite quantum dot has a chemical formula of CsPb(ClₐBr₁₋ₐ)₃, wherein 0<a≦1, the all-inorganic perovskite quantum dot is a blue quantum dot.

7. The light emitting device according to claim 6, wherein the second light emitted from the blue quantum dot has a wave peak of 400 nm to 500 nm, a FWHM of 10 nm to 30 nm.

8. The light emitting device according to claim 1, wherein the all-inorganic perovskite quantum dot is a red quantum dot having a particle diameter in a range of 10 nm to 14 nm, or a green quantum dot having a particle diameter in a range of 8 nm to 12 nm, or a blue quantum dot having a particle diameter in a range of 7 nm to 10 nm.

9. The light emitting device according to claim 1, wherein the all-inorganic perovskite quantum dot comprises a first all-inorganic perovskite quantum dot and a second all-inorganic perovskite quantum dot, the first all-inorganic perovskite quantum dot and the second all-inorganic perovskite quantum dot have the chemical formula of CsPb(ClₐBr_{1-a-b}I_{b})₃, wherein 0≦a≦1, 0≦b≦1, the first all-inorganic perovskite quantum dot and the second all-inorganic perovskite quantum dot have different characteristics, wherein the first all-inorganic perovskite quantum dot and the second all-inorganic perovskite quantum dot have different a or different b, and/or have different particle diameters.

10. The light emitting device according to claim 9, wherein the first all-inorganic perovskite quantum dot and the second all-inorganic perovskite quantum dot having different characteristics are selected from the group consisting of a red quantum dot having a chemical formula of CsPb(Br_{1-b}I_{b})₃ with 0.5≦b≦1, a green quantum dot having a chemical formula of CsPb(Br_{1-b}I_{b})₃ with 0≦b<0.5, and a blue quantum dot having a chemical formula of CsPb(ClₐBr₁₋ₐ)₃ with 0<a≦1.

11. The light emitting device according to claim 9, wherein the first all-inorganic perovskite quantum dot and the second all-inorganic perovskite quantum dot having different characteristics are selected from the group consisting of a red quantum dot having a particle diameter in a range of 10 nm to 14 nm, a green quantum dot having a particle diameter in a range of 8 nm to 12 nm, and a blue quantum dot having a particle diameter in a range of 7 nm to 10 nm.

12. The light emitting device according to claim 9, wherein the first all-inorganic perovskite quantum dot and the second all-inorganic perovskite quantum dot having different characteristics have a chemical formula of CsPb(Br_{1-b}I_{b})₃, the b of the first all-inorganic perovskite quantum dot is 0, the b of the second all-inorganic perovskite quantum dot is 1.

13. The light emitting device according to claim 1, comprising a wavelength converting layer on a light emitting side of the light emitting diode chip, wherein the wavelength converting layer comprises the wavelength-converting material.

14. The light emitting device according to claim 13, comprising:
a plurality of the wavelength converting layers apart from each other on the light emitting side of the light emitting diode chip; and
spacing layers between the plurality of the wavelength converting layers, the spacing layers comprising a light absorbing material or a reflective material.

15. The light emitting device according to claim 14, being a micro light emitting diode.

16. The light emitting device according to claim 14, wherein the light emitting diode chip having a first electrode and a second electrode on opposing sides of the light emitting diode chip, the light emitting side of the light emitting diode chip and the first electrode are on the same side of the light emitting diode chip.

17. The light emitting device according to claim 14, being applied for a display, and comprising pixels each comprising at least a red sub pixel, a green sub pixel and a blue sub pixel,
each of the red sub pixel, the green sub pixel and the blue sub pixel comprises one of the plurality of the wavelength converting layers, wherein,
the all-inorganic perovskite quantum dot of the wavelength converting layer corresponding to the red sub pixel has a chemical formula of CsPb(Br_{1-b}I_{b})₃ with 0.5≦b≦1, and/or has a particle diameter in a range of 10 nm to 14 nm, and/or
the all-inorganic perovskite quantum dot of the wavelength converting layer corresponding to the green sub pixel has a chemical formula of CsPb(Br_{1-b}I_{b})₃ with 0≦b<0.5, and/or has a particle diameter in a range of 8 nm to 12 nm, and/or
the all-inorganic perovskite quantum dot of the wavelength converting layer corresponding to the blue sub pixel has a chemical formula of CsPb(ClₐBr₁₋ₐ)₃ with 0<a≦1, and/or has a particle diameter in a range of 7 nm to 10 nm.

18. The light emitting device according to claim 17, wherein the each of the pixels further comprises a white sub pixel comprising another one of the plurality of the wavelength converting layers, and separated from the red sub pixel, the green sub pixel and the blue sub pixel by the spacing layers.

19. The light emitting device according to claim 13, wherein the wavelength converting layer further comprises a transparent material, the wavelength-converting material is doped in the transparent material.

20. The light emitting device according to claim 13, comprising a plurality of the wavelength converting layers stacked and having emission wavelengths different from each other.

21. The light emitting device according to claim 13, further comprising a transparent gel packaging the wavelength converting layer and the light emitting diode chip.

22. The light emitting device according to claim 13, further comprising a structural element disposed by an arrangement selecting from the following designs:
the structural element having a receiving region with the wavelength converting layer received therein, and covering an upper surface and a lower surface of the wavelength converting layer for supporting, packaging, protecting the wavelength converting layer;
the structural element being on the lower surface of the wavelength converting layer, and having the receiving region with the wavelength converting layer received therein and supporting the wavelength converting layer; and
the structural element being on the upper surface of the wavelength converting layer for protecting the wavelength converting layer.

23. The light emitting device according to claim 13, further comprising a reflective wall outside of the wavelength converting layer.

24. The light emitting device according to claim 1, being applied for a back light module, a pixel or a sub pixel of a display, or a lighting device.

25. The light emitting device according to claim 1, comprising at least two kinds of the all-inorganic perovskite quantum dots having a chemical formula of CsPb(Br_{1-b}I_{b})₃ with different b, and a NTSC of the light emitting device is equal to or higher than 90%.

26. The light emitting device according to claim 1, comprising at least four kinds of the all-inorganic perovskite quantum dot having a chemical formula or CsPb(Br_{1-b}I_{b})₃ with different b, wherein the light emitting device has a general color rendering index (Ra) of being equal to or higher than 75.

27. A wavelength-converting material, comprising at least two kinds of all-inorganic perovskite quantum dots having different characteristics and having a chemical formula of CsPb(ClₐBr_{1-a-b}I_{b})₃, wherein 0≦a≦1, 0≦b≦1.

28. The wavelength-converting material according to claim 27, wherein the at least two kinds of all-inorganic perovskite quantum dots having different characteristics have different a or different b, or/and different particle diameters.
